(19) United States
(12) Patent Application Publication
(10) Pub. No.: US 2023/0345631 A1
(43) Pub. Date: Oct. 26, 2023

(54) PREPREG, METAL-CLAD LAMINATE, AND PRINTED WIRING BOARD

(71) Applicant: JSR CORPORATION, Tokyo (JP)

(72) Inventors: Nobuyuki MIYAKI, Minato-ku, Tokyo (JP); Naoyuki KAWASHIMA, Minato-ku, Tokyo (JP); Yuutoku YAMASHITA, Minato-ku, Tokyo (JP); Shouma ANABUKI, Minato-ku, Tokyo (JP); Kenta NISHINO, Minato-ku, Tokyo (JP); Takeru KAMEYAMA, Minato-ku Tokyo (JP)

(73) Assignee: JSR CORPORATION, Tokyo (JP)

(21) Appl. No.: 18/023,760

(22) PCT Filed: Aug. 19, 2021
(86) PCT No.: PCT/JP2021/030351

§ 371 Date: Feb. 28, 2023

(30) Foreign Application Priority Data
Sep. 1, 2020 (JP) 2020-146667

(51) Int. Cl. H05K 1/03; B32B 15/08; C08J 5/24; H05K 3/46

(52) U.S. Cl. CPC H05K 1/0366; B32B 15/08; C08J 5/244; C08J 5/247; H05K 3/4652; H05K 2203/176; B32B 2305/076

(57) ABSTRACT

Provided is a prepreg for producing a multilayer printed wiring board having high reliability and being excellent in adhesiveness with respect to a base material or the like. The prepreg includes: a base material; and a polymer having a structural unit represented by at least one kind of the following formulae (1-1), (1-2), and (1-3).

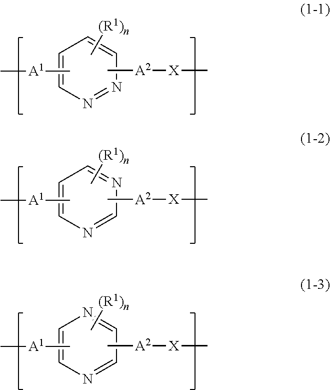

### TECHNICAL FIELD

The present invention relates to a prepreg, a metal-clad laminate, and a printed wiring board.

### BACKGROUND ART

In recent years, various kinds of electronic equipment, especially mobile and other communication equipment, have been undergoing rapid developments in packaging technologies, such as high integration of semiconductor devices to be mounted, an increase in density of wiring, multilayering, and high-frequency adaptation, along with an increase in amount of information processed. Accordingly, a printed wiring board or the like to be used in various kinds of electronic equipment is required not only to have high levels of heat resistance and the like, but also to reduce a loss at the time of signal transmission in order to increase a transmission speed of an electric signal including a high frequency band. In order to satisfy the requirements, a material having a lower dielectric constant and dielectric loss tangent is needed as a substrate material for an insulating layer to be used for the wiring board.

A polyphenylene ether resin (PPE) is excellent in high-frequency characteristics (dielectric characteristics), such as dielectric constant and dielectric loss, and is used as an insulating material for a printed wiring board for mobile and other electronic equipment utilizing a high frequency band (see, for example, Patent Literature 1).

### CITATION LIST

### Patent Literature

[PTL 1] JP 2010-53178 A

### SUMMARY OF INVENTION

### Technical Problem

However, in general, a high-molecular-weight PPE has a high melting point, and does not have sufficient adhesiveness with respect to a base material and other members. Accordingly, when a prepreg to be used for producing a general multilayer printed wiring board is formed using the PPE, the melt viscosity of the prepreg is increased to cause a molding failure, such as a void or a thin spot, at the time of multilayer molding, resulting in problems in that: a multilayer printed wiring board having high reliability is difficult to obtain; and the adhesiveness with respect to the base material or the like is insufficient.

### Solution to Problem

The present invention has been made to solve at least part of the above-mentioned problems, and can be achieved as any one of the following aspects.

According to one aspect of the present invention, there is provided a prepreg, including: a base material; and a polymer having a structural unit represented by at least one kind of the following formulae (1-1), (1-2), and (1-3):

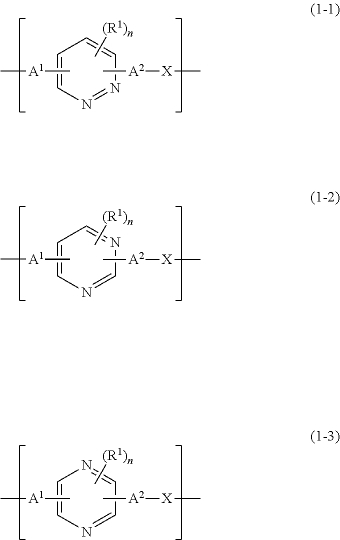

in the formulae (1-1) to (1-3), R¹s each independently represent a halogen atom, a monovalent hydrocarbon group having 1 to 20 carbon atoms, a monovalent halogenated hydrocarbon group having 1 to 20 carbon atoms, a nitro group, a cyano group, a primary to tertiary amino group, or a salt of a primary to tertiary amino group, “n”s each independently represent an integer of from 0 to 2, and when “n” represents 2, a plurality of R¹s may be identical to or different from each other, or may be bonded to each other in an arbitrary combination to form part of a ring structure, A¹ and A² each independently represent —O—, —S—, or —N(R²)—, R² represents a hydrogen atom, a monovalent hydrocarbon group having 1 to 20 carbon atoms, or a monovalent halogenated hydrocarbon group having 1 to 20 carbon atoms, and X represents a divalent organic group.

In the prepreg according to the one aspect, the divalent organic group represented by the X in the formulae (1-1) to (1-3) may contain a group represented by the following formula (2-1):

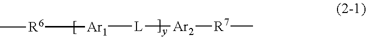

in the formula (2-1), Ar₁ and Ar₂ each independently represent a substituted or unsubstituted aromatic hydrocarbon group, L represents a single bond, —O—, —S—, —N(R⁸), C═O, —SO₂—, P═O, or a divalent organic group, R represents a hydrogen atom, a monovalent hydrocarbon group having 1 to 20 carbon atoms, or a monovalent halogenated hydrocarbon group having 1 to 20 carbon atoms, “y” represents an integer of from 0 to 5, and when “y” represents 2 or more, a plurality of Ls may be identical to or different from each other, and R⁶ and R⁷ each independently represent a single bond, a methylene group, or an alkylene group having 2 to 4 carbon atoms.

The prepreg according to any one of the above-mentioned aspects may further include a curable compound.

The prepreg according to any one of the above-mentioned aspects may further include: a curing aid; a flame retardant; and an inorganic filler.

In the prepreg according to any one of the above-mentioned aspects, the base material may be a glass cloth, and the glass cloth may have a dielectric constant of 6.8 or less.

According to one aspect of the present invention, there is provided a metal-clad laminate, which is obtained by laminating the prepreg of any one of the above-mentioned aspects and metal foil, followed by curing.

According to one aspect of the present invention, there is provided a printed wiring board, including the metal-clad laminate of the one aspect from which part of the metal foil has been removed.

### Advantageous Effects of Invention

The prepreg according to the present invention enables the production of a metal-clad laminate and a multilayer printed wiring board each having high reliability and being excellent in adhesiveness with respect to the base material or the like.

### DESCRIPTION OF EMBODIMENTS

Preferred embodiments of the present invention are described in detail below. It should be appreciated that the present invention is not limited to the following embodiments, and includes various modification examples performed within the scope that does not change the gist of the present invention.

Herein, a numerical range described with the expression “from X to Y” is meant to include a numerical value X as a lower limit value and a numerical value Y as an upper limit value.

### 1. PREPREG

A prepreg according to one embodiment of the present invention contains: a base material; and a polymer having a structural unit represented by at least one kind of the following formulae (1-1), (1-2), and (1-3).

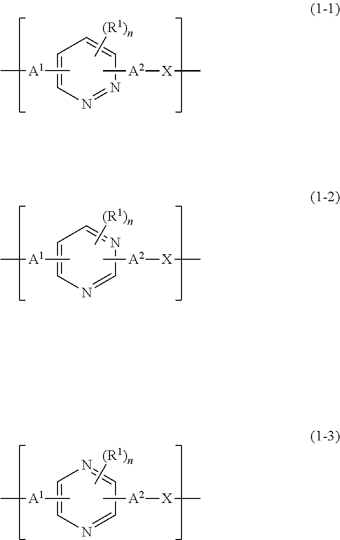

In the formulae (1-1) to (1-3), R¹s each independently represent a halogen atom, a monovalent hydrocarbon group having 1 to 20 carbon atoms, a monovalent halogenated hydrocarbon group having 1 to 20 carbon atoms, a nitro group, a cyano group, a primary to tertiary amino group, or a salt of a primary to tertiary amino group, “n”s each independently represent an integer of from 0 to 2, and when “n” represents 2, a plurality of R¹s may be identical to or different from each other, or may be bonded to each other in an arbitrary combination to form part of a ring structure, A¹ and A² each independently represent —O—, —S—, or —N(R₂)—, R² represents a hydrogen atom, a monovalent hydrocarbon group having 1 to 20 carbon atoms, or a monovalent halogenated hydrocarbon group having 1 to 20 carbon atoms, and X represents a divalent organic group.

The materials contained in the prepreg according to this embodiment, the physical properties thereof, and the like are described in detail below.

1.1. Base Material

Examples of the base material include: various glass cloths, such as a roving cloth, a cloth, a chopped mat, and a surfacing mat; a boron fiber, an alumina fiber, a silicon nitride fiber, an asbestos fabric, a metal fiber fabric, and other synthetic or natural inorganic fiber fabrics; woven fabrics or non-woven fabrics each obtained from a liquid crystal fiber, such as a wholly aromatic polyamide fiber, a wholly aromatic polyester fiber, or a polybenzoxazole fiber; natural fiber fabrics, such as a cotton fabric, a hemp fabric, and a felt; natural cellulose-based base materials, such as a carbon fiber fabric, kraft paper, cotton paper, and a fabric obtained from a paper-glass-mixed yarn; and a polytetrafluoroethylene porous film. Those base materials are used alone or in combination thereof.

Of those base materials, a glass cloth is preferred. The dielectric constant of the glass cloth is preferably 6.8 or less, more preferably 5.1 or less, still more preferably 4.9 or less. When the base material is the glass cloth, there is a tendency that the laminate can be further improved in heat resistance and can be further reduced in thermal expansion coefficient. When the dielectric constant of the glass cloth is 6.8 or less, there is a tendency that an increase in dielectric constant of the laminate can be further reduced.

Herein, the “dielectric constant of the glass cloth” refers to a value at 1 GHz measured by a cavity resonance method to be described later, using a sample processed into a lump instead of a cloth.

The ratio of the solid content of the resin composition in the prepreg according to this embodiment is preferably from 30 mass % to 80 mass %, more preferably from 40 mass % to 70 mass %. When the ratio is 30 mass % or more, in the case where the prepreg is used for an electronic substrate or the like, there is a tendency that insulation reliability is further excellent. When the ratio is 80 mass % or less, in the case where the prepreg is used for an electronic substrate or the like, there is a tendency that mechanical characteristics, such as processability and a bending elastic modulus, are excellent.

1.2. Polymer

The prepreg according to this embodiment contains, as a polymer, a polymer having at least one kind of repeating unit out of repeating units represented by the following general formulae (1-1), (1-2), and (1-3) (hereinafter sometimes referred to as “specific polymer”).

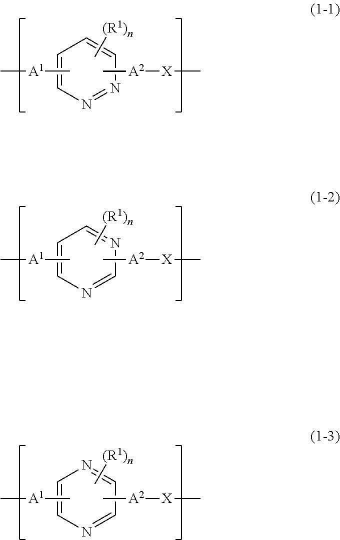

In the formulae (1-1) to (1-3), R¹s each independently represent a halogen atom, a monovalent hydrocarbon group having 1 to 20 carbon atoms, a monovalent halogenated hydrocarbon group having 1 to 20 carbon atoms, a nitro group, a cyano group, a primary to tertiary amino group, or a salt of a primary to tertiary amino group, “n”s each independently represent an integer of from 0 to 2, and when “n” represents 2, a plurality of R¹s may be identical to or different from each other, or may be bonded to each other in an arbitrary combination to form part of a ring structure, A¹ and A² each independently represent —O—, —S—, or —N(R²)—, R² represents a hydrogen atom, a monovalent hydrocarbon group having 1 to 20 carbon atoms, or a monovalent halogenated hydrocarbon group having 1 to 20 carbon atoms, and X represents a divalent organic group.

Examples of the halogen atom represented by R¹ include a fluorine atom, a chlorine atom, a bromine atom, and an iodine atom.

Examples of the monovalent hydrocarbon group having 1 to 20 carbon atoms represented by R¹ include a monovalent chain hydrocarbon group, a monovalent alicyclic hydrocarbon group, and a monovalent aromatic hydrocarbon group.

Examples of the monovalent chain hydrocarbon group include: alkyl groups, such as a methyl group, an ethyl group, a n-propyl group, an isopropyl group, a n-butyl group, an isobutyl group, a sec-butyl group, a tert-butyl group, and a n-pentyl group; alkenyl groups, such as an ethenyl group, a propenyl group, a butenyl group, and a pentenyl group; and alkynyl groups, such as an ethynyl group, a propynyl group, a butynyl group, and a pentynyl group.

Examples of the monovalent alicyclic hydrocarbon group include: monocyclic cycloalkyl groups, such as a cyclopropyl group, a cyclobutyl group, a cyclopentyl group, and a cyclohexyl group; polycyclic cycloalkyl groups, such as a norbornyl group and an adamantyl group; monocyclic cycloalkenyl groups, such as a cyclopropenyl group, a cyclobutenyl group, a cyclopentenyl group, and a cyclohexenyl group; and polycyclic cycloalkenyl groups such as a norbornenyl group.

Examples of the monovalent aromatic hydrocarbon group include: aryl groups, such as a phenyl group, a tolyl group, a xylyl group, a naphthyl group, and an anthryl group; and aralkyl groups, such as a benzyl group, a phenethyl group, a phenylpropyl group, and a naphthyimethyl group.

Examples of the monovalent halogenated hydrocarbon group having 1 to 20 carbon atoms represented by R¹ include groups each obtained by substituting part or all of the hydrogen atoms of the monovalent hydrocarbon group having 1 to 20 carbon atoms given as an example of the group represented by R¹ with a halogen atom, such as a fluorine atom, a chlorine atom, a bromine atom, or an iodine atom.

Substituents in the secondary amino group and the tertiary amino group each represented by R¹ are not particularly limited, but are each, for example, the monovalent hydrocarbon group having 1 to 20 carbon atoms given as an example of the group represented by R¹. A cation serving as a cationic moiety in the salt of a primary to tertiary amino group represented by R¹ is not particularly limited, and may be a known cation such as Na⁺.

From the viewpoints of improvements in polymerization reactivity and solubility of the monomer, R¹ represents preferably a halogen atom, a monovalent hydrocarbon group having 1 to 6 carbon atoms, a monovalent halogenated hydrocarbon group having 1 to 6 carbon atoms, a nitro group, a cyano group, a primary to tertiary amino group, or a salt of a primary to tertiary amino group, more preferably a fluorine atom, a chlorine atom, a methyl group, a nitro group, a cyano group, a tert-butyl group, a phenyl group, or an amino group. From the same viewpoints, “n” represents preferably 0 or 1, more preferably 0.

R² represents a hydrogen atom, or a monovalent hydrocarbon group having 1 to 20 carbon atoms or a monovalent halogenated hydrocarbon group having 1 to 20 carbon atoms. The monovalent hydrocarbon group having 1 to 20 carbon atoms represented by R² is, for example, the monovalent hydrocarbon group having 1 to 20 carbon atoms given as an example of the group represented by R¹. In addition, part or all of the hydrogen atoms of the hydrocarbon group represented by R² may be substituted with an ester group or a sulfonyl group.

From the viewpoint of an improvement in polymerization reactivity of a monomer, R² preferably represents a hydrogen atom or a monovalent hydrocarbon group having 1 to 10 carbon atoms. In addition, when A¹ and A² both represent —N(R²)—, the two R²s may be identical to or different from each other.

The position of one bonding site of the repeating unit relative to the other bonding site is not particularly limited, but a meta position is preferred for improving the polymerization reactivity of a monomer that provides the repeating unit. In addition, the repeating unit is preferably the repeating unit represented by the general formula (1-2) having a pyrimidine skeleton from the viewpoint of an improvement in polymerization reactivity of the monomer, and the viewpoint of an improvement in solubility thereof in various organic solvents.

Examples of such monomer that provides the repeating unit include 4,6-dichloropyrimidine, 4,6-dibromopyrimidine, 2,4-dichloropyrimidine, 2,5-dichloropyrimidine, 2,5-dibromopyrimidine, 5-bromo-2-chloropyrimidine, 5-bromo-2-fluoropyrimidine, 5-bromo-2-iodopyrimidine, 2-chloro-5-fluoropyrimidine, 2-chloro-5-iodopyrimidine, 2,4-dichloro-5-fluoropyrimidine, 2,4-dichloro-5-iodopyrimidine, 5-chiro-2,4,6-trifluoropyrimidine, 2,4,6-trichloropyrimidine, 4,5,6-trichloropyrimidine, 2,4,5-trichloropyrimidine, 2,4,5,6-tetrachloropyrimidine, 2-phenyl-4,6-dichloropyrimidine, 2-methylthio-4,6-dichloropyrimidine, 2-methylsulfonyl-4,6-dichloropyrimidine, 2-amino-4,6-dichloropyrimidine, 5-amino-4,6-dichloropyrimidine, 2,5-diamino-4,6-dichloropyrimidine, 4-amino-2,6-dichloropyrimidine, 4,6-dichloro-5-methoxypyrimidine, 2,4-dichloro-2-methoxypyrimidine, 2,4-dichloro-5-fluoro-pyrimidine, 5-bromo-2,4-dichloropyrimidine, 2,4-dichloro-5-iodopyrimidine, 4,6-dichloro-2-methylpyrimidine, 4,6-dichloro-5-methylpyrimidine, 2,4-dichloro-6-methylpyrimidine, 2,4-dichloro-5-methylpyrimidine, 2,4-dichloro-5-nitropyrimidine, 4-amino-2-chloro-5-fluoropyrimidine, 5-amino-4,6-dichloro-2-methylpyrimidine, 5-bromo-4-chloro-2-methylthiopyrimidine, 3,6-dichloropyridazine, 3,5-dichloropyridazine, 3,6-dichloro-4-methylpyridazine, 2,3-dichloropyrazine, 2,6-dichloropyrazine, 2,5-dibromopyrazine, 2,6-dibromopyrazine, 2-amino-3,5-dibromopyrazine, and 5,6-dicyano-2,3-dichloropyrazine. Those monomers may be used alone or in combination thereof.

A¹ and A² in the formulae (1-1), (1-2), and (1-3) each independently represent —O—, —S—, or —N(R²)—. A case in which A¹ and A² each represent —O— is preferred in terms of flexibility, solubility, and heat resistance. A case in which A¹ and A² each represent —N(R²)— is preferred in terms of adhesiveness and the like. Here, R² represents a hydrogen atom or a monovalent hydrocarbon group having 1 to 20 carbon atoms, and may contain an ester group or a sulfonyl group.

The specific polymer preferably contains a group represented by the following formula (2-1) as the divalent organic group represented by X in the formulae (1-1), (1-2), and (1-3).

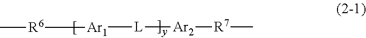

In the formula (2-1), Ar₁ and Ar₂ each independently represent a substituted or unsubstituted aromatic hydrocarbon group, L represents a single bond, —O—, —S—, —N(R⁸), C═O, —SO₂—, P═O, or a divalent organic group, R⁸ represents a hydrogen atom, a monovalent hydrocarbon group having 1 to 20 carbon atoms, or a monovalent halogenated hydrocarbon group having 1 to 20 carbon atoms, “y” represents an integer of from 0 to 5, and when “y” represents 2 or more, a plurality of Ls may be identical to or different from each other, and R⁶ and R⁷ each independently represent a single bond, a methylene group, or an alkylene group having 2 to 4 carbon atoms.

The aromatic hydrocarbon groups represented by Arₙ and Ar₂ are each independently preferably an aromatic hydrocarbon group having 6 or more and 30 or less carbon atoms, more preferably any one kind of a phenyl group, a naphthyl group, and an anthryl group, particularly preferably a phenyl group or a naphthyl group.

In addition, the aromatic hydrocarbon groups represented by Ar₁ and Ar₂ may each have 1 to 8 substituents. The number of substituents of each of the aromatic hydrocarbon groups represented by Ar₁ and Ar₂ is preferably from 0 to 8, more preferably from 0 to 4, particularly preferably from 0 to 2 from the viewpoint of an improvement in polymerization reactivity of the monomer.

The substituent is not particularly limited, but is a halogen atom, a monovalent hydrocarbon group having 1 to 20 carbon atoms, a monovalent halogenated hydrocarbon group having 1 to 20 carbon atoms, an alkoxy group having 1 to 20 carbon atoms, an alkylthio group having 1 to 20 carbon atoms, a nitro group, a cyano group, a carboxy group, a sulfonic acid group, a phosphonic acid group, a phosphoric acid group, a hydroxy group, a primary to tertiary amino group, a salt of a carboxy group, a salt of a sulfonic acid group, a salt of a phosphonic acid group, a salt of a phosphoric acid group, a salt of a hydroxy group, or a salt of a primary to tertiary amino group.

Examples of the halogen atom include a fluorine atom, a chlorine atom, a bromine atom, and an iodine atom.

The monovalent hydrocarbon group having 1 to 20 carbon atoms is, for example, the monovalent hydrocarbon group having 1 to 20 carbon atoms given as an example of the group represented by R¹ in the formulae (1-1) to (1-3).

Examples of the monovalent halogenated hydrocarbon group having 1 to 20 carbon atoms include groups each obtained by substituting part or all of the hydrogen atoms of the monovalent hydrocarbon group having 1 to 20 carbon atoms given as an example of the group represented by R¹ in the formulae (1-1) to (1-3) with a halogen atom, such as a fluorine atom, a chlorine atom, a bromine atom, or an iodine atom.

Examples of the alkoxy group having 1 to 20 carbon atoms include a methoxy group, an ethoxy group, a n-propoxy group, an isopropoxy group, a butoxy group, a pentyloxy group, a hexyloxy group, and an octyloxy group.

Examples of the alkylthio group having 1 to 20 carbon atoms include a methylthio group, an ethylthio group, a n-propylthio group, an isopropylthio group, a butylthio group, a pentylthio group, a hexylthio group, and an octylthio group.

Substituents in the secondary amino group and the tertiary amino group are not particularly limited, but are each, for example, the monovalent hydrocarbon group having 1 to 20 carbon atoms given as an example of the group represented by R¹.

A cation serving as a cationic moiety in each of the salt of a carboxy group, the salt of a sulfonic acid group, the salt of a phosphonic acid group, the salt of a phosphoric acid group, the salt of a hydroxy group, and the salt of a primary to tertiary amino group is not particularly limited, and may be a known cation such as Na⁺.

From the viewpoint of an improvement in polymerization reactivity of the monomer, the substituents of the aromatic hydrocarbon groups represented by Ar₁ and Ar₂ are each preferably a halogen atom, a monovalent hydrocarbon group having 1 to 3 carbon atoms, a monovalent halogenated hydrocarbon group having 1 to 3 carbon atoms, an alkoxy group having 1 to 3 carbon atoms, an alkylthio group having 1 to 3 carbon atoms, a nitro group, a cyano group, a carboxy group, a sulfonic acid group, a phosphonic acid group, a phosphoric acid group, a hydroxy group, a primary to tertiary amino group, a salt of a carboxy group, a salt of a sulfonic acid group, a salt of a phosphonic acid group, a salt of a phosphoric acid group, a salt of a hydroxy group, or a salt of a primary to tertiary amino group, more preferably a fluorine atom, a chlorine atom, a methyl group, an ethyl group, a fluoromethyl group, a methoxy group, a methylthio group, a nitro group, a cyano group, a carboxy group, a sulfonic acid group, a phosphonic acid group, a phosphoric acid group, a hydroxy group, a primary to tertiary amino group, a salt of a carboxy group, a salt of a sulfonic acid group, a salt of a phosphonic acid group, a salt of a phosphoric acid group, a salt of a hydroxy group, or a salt of a primary to tertiary amino group. From the same viewpoint, “a” and “b” each represent preferably from 0 to 8, more preferably from 0 to 4, particularly preferably from 0 to 2. Further, from the same viewpoint, “c” and “d” each represent preferably from 0 to 2, more preferably represent 0 or 1.

Examples of the divalent organic group having 1 to 20 carbon atoms represented by L include a methylene group, an alkylene group having 2 to 20 carbon atoms, a halogenated methylene group, a halogenated alkylene group having 2 to 20 carbon atoms, and a divalent cardo structure.

Examples of the alkylene group having 2 to 20 carbon atoms represented by L include an ethylene group, a n-propylene group, an isopropylene group, a n-butylene group, a sec-butylene group, a tert-butylene group, a neopentylene group, a 4-methyl-pentane-2-diyl group, and a nonane-1,9-diyl group.

Examples of the halogenated methylene group represented by L include groups each obtained by substituting part or all of the hydrogen atoms of a methylene group with a halogen atom, such as a fluorine atom, a chlorine atom, a bromine atom, or an iodine atom.

Examples of the halogenated alkylene group having 2 to 20 carbon atoms represented by L include groups each obtained by substituting part or all of the hydrogen atoms of the alkylene group having 2 to 20 carbon atoms given as an example of the group represented by L with a halogen atom, such as a fluorine atom, a chlorine atom, a bromine atom, or an iodine atom.

Examples of the divalent cardo structure represented by L include a divalent group derived from fluorene (i.e., a group obtained by removing two hydrogen atoms from fluorene), a divalent group derived from phenolphthalein (i.e., a group obtained by removing two hydrogen atoms from phenolphthalein), and a group represented by the following formula (L1). In each of the divalent group derived from fluorene and the divalent group derived from phenolphthalein, part or all of the hydrogen atoms may be substituted with a monovalent chain hydrocarbon group having 1 to 20 carbon atoms, and moreover, part or all of the hydrogen atoms including those of the substituent(s) may be substituted with a fluorine atom.

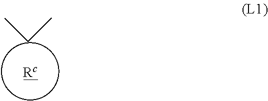

In the formula (L1), R^{c} represents a divalent alicyclic hydrocarbon group having 5 to 30 ring members.

Examples of the divalent alicyclic hydrocarbon group having 5 to 30 ring members represented by R¹ include a monocyclic alicyclic hydrocarbon group having 5 to 15 ring members, a monocyclic fluorinated alicyclic hydrocarbon group having 5 to 15 ring members, a polycyclic alicyclic hydrocarbon group having 7 to 30 ring members, and a polycyclic fluorinated alicyclic hydrocarbon group having 7 to 30 ring members.

Examples of the monocyclic alicyclic hydrocarbon group having 5 to 15 ring members include a cyclopentane-1,1-diyl group, a cyclohexane-1,1-diyl group, a 3,3,5-trimethylcyclohexane-1,1-diyl group, a cyclopentene-3,3-diyl group, a cyclohexene-3,3-diyl group, a cyclooctane-1,1-diyl group, a cyclodecane-1,1-diyl group, a cyclododecane-1,1-diyl group, and a group obtained by substituting part or all of the hydrogen atoms of each of the groups with a monovalent chain hydrocarbon group having 1 to 20 carbon atoms.

Examples of the monocyclic fluorinated alicyclic hydrocarbon group having 5 to 15 ring members include groups each obtained by substituting part or all of the hydrogen atoms of each of the groups given as the examples of the monocyclic alicyclic hydrocarbon group having 5 to 15 ring members with a fluorine atom.

Examples of the polycyclic alicyclic hydrocarbon group having 7 to 30 ring members include: groups each obtained by removing 2 hydrogen atoms bonded to 1 carbon atom of a polycyclic alicyclic hydrocarbon, such as norbornane, norbornene, adamantane, tricyclo[5.2.1.0²¹⁶]decane, tricyclo[5.2.1.0²° 6]heptane, pinane, camphane, decalin, nortricyclane, perhydroanthracene, perhydroazulene, cyclopentanohydrophenanthrene, or bicyclo[2.2.2]-2-octene; and groups each obtained by substituting part or all of the hydrogen atoms of each of the groups with a monovalent chain hydrocarbon group having 1 to 20 carbon atoms.

Examples of the polycyclic fluorinated alicyclic hydrocarbon group having 7 to 30 ring members include groups each obtained by substituting part or all of the hydrogen atoms of each of the groups given as the examples of the polycyclic alicyclic hydrocarbon group having 7 to 30 ring members with a fluorine atom.

From the viewpoint of the structural stability of the polymer, L preferably represents a single bond, —O—, —S—, —C(O)—, —S(O)—, —S(O)₂—, —C(O)—NH—, —C(O)—O—, a methylene group, an alkylene group having 2 to 5 carbon atoms, a halogenated methylene group, a halogenated alkylene group having 2 to 10 carbon atoms, or a divalent cardo structure. From the same viewpoint, “y” represents preferably from 0 to 4, more preferably from 0 to 3.

Examples of the alkylene group having 2 to 4 carbon atoms represented by each of R⁶ and R⁷ include an ethylene group, a n-propylene group, an isopropylene group, a n-butylene group, a sec-butylene group, and a tert-butylene group. R⁶ and R each preferably represent a single bond, a methylene group, or an ethylene group from the viewpoint of an improvement in polymerization reactivity of the monomer.

“y” represents an integer of from 0 to 5. From the viewpoints of an improvement in solubility of the polymer and the impartment of flexibility thereto, “y” preferably represents 1 or more. In addition, when “y” represents 2 or more, a plurality of Ls may be identical to or different from each other.

The content of the repeating units represented by the general formulae (1-1), (1-2), and (1-3) in the specific polymer is preferably from 1 mol % to 95 mol %, more preferably from 5 mol % to 80 mol % when the total of all repeating units in the specific polymer is defined as 100 mol %.

A method of synthesizing the specific polymer is not particularly limited, and a known method may be used. For example, the specific polymer may be synthesized by heating a monomer that provides at least one kind of repeating unit out of the repeating units represented by the general formulae (1-1), (1-2), and (1-3), and as required, any other monomer, in an organic solvent together with an alkali metal or the like.

The lower limit of the weight-average molecular weight (Mw) of the specific polymer is preferably 500, more preferably 1,000, still more preferably 2,000, particularly preferably 3,000. The upper limit of the weight-average molecular weight (Mw) is preferably 600,000, more preferably 300,000, particularly preferably 200,000.

The lower limit of the glass transition temperature (Tg) of the specific polymer is preferably 70° C., more preferably 80° C. The upper limit of the glass transition temperature (Tg) is preferably 320° C., more preferably 300° C. from the standpoint of processability.

Examples of those specific polymers may include polymers described in JP 2015-209511 A, WO 2016/143447 A1, JP 2017-197725 A, and JP 2018-024827 A.

The prepreg according to this embodiment contains the specific polymer, and hence enables the production of a printed wiring board having low dielectric characteristics for reducing crosstalk between wires, and low dielectric loss characteristics for reducing a signal loss. In addition, by virtue of containing the specific polymer, the prepreg according to this embodiment does not cause a molding failure, such as a void or a thin spot, at the time of multilayer molding, and hence provides a multilayer printed wiring board having high reliability and also achieves satisfactory adhesiveness with respect to the base material such as a glass cloth.

### 2. METHOD OF PRODUCING PREPREG

A method of producing a prepreg according to one embodiment of the present invention includes a step of impregnating or coating a base material with a composition containing the above-mentioned specific polymer (hereinafter sometimes referred to as “resin composition”). Specifically, the above-mentioned prepreg may be produced by, for example, impregnating the base material such as a glass cloth with the resin composition, or coating the base material such as a glass cloth with the resin composition, and then drying and removing a solvent contained in the resin composition.

As a method of impregnating or coating the base material with the resin composition, there are given, for example: a method making use of dipping, roll coating die coating, bar coating, or the like; and spraying. In addition, a method of drying and removing the solvent is not particularly limited, but is, for example, a method involving heating and/or drying the solvent with a hot-air dryer or the like.

The prepreg produced by such method may be a prepreg including the base material, and the resin composition or a semi-cured product of the resin composition. An example of such prepreg is a prepreg in which a fibrous base material is present in the semi-cured product. That is, this prepreg includes the semi-cured product of the resin composition, and a fibrous base material present in the semi-cured product.

The “semi-cured product” is a product in a state in which the resin composition has been partially cured to such a degree as to be able to be further cured. That is, the semi-cured product is a product in a state in which the resin composition has been semi-cured (B-staged). For example, when the resin composition is heated, first, its viscosity is gradually reduced, and then curing is initiated to gradually increase the viscosity. In such case, an example of the semi-curing is a state during a period after the start of the increase of the viscosity and before complete curing.

In addition, the prepreg obtained using the resin composition may be a prepreg including the semi-cured product of the resin composition as described above, or may be a prepreg including the resin composition in an uncured state. That is, the prepreg may be a prepreg including the semi-cured product of the resin composition (B-stage resin composition) and the base material, or may be a prepreg including an uncured resin composition (A-stage resin composition) and the base material.

Components contained in the resin composition are described in detail below.

2.1. Resin Composition

The resin composition may contain, in addition to the above-mentioned specific polymer, another polymer, a curable compound, a curing aid, a flame retardant, an inorganic filler, a solvent, and the like.

<Specific Polymer>

The structure and physical properties of the specific polymer have been described above, and hence their description is omitted.

The content of the specific polymer in the resin composition is preferably 5 mass % or more, more preferably 10 mass % or more, still more preferably 15 mass % or more, particularly preferably 20 mass % or more when the total of the specific polymer, the other polymer, and the curable compound is defined as 100 mass %. In addition, the content of the specific polymer in the resin composition is preferably 100 mass % or less, more preferably 80 mass % or less, still more preferably 60 mass % or less, particularly preferably 50 mass % or less when the total of the specific polymer, the other polymer, and the curable compound is defined as 100 mass %. When the content of the specific polymer falls within the above-mentioned ranges, a multilayer printed wiring board excellent in reliability and low dielectric characteristics, and also excellent in adhesiveness with respect to the base material or the like can be produced in some cases.

<Other Polymer>

As the other polymer, for example, a known material having the characteristics of a low dielectric constant and a low dielectric loss tangent, such as polyimide, polyarylate, or polyarylene ether, may be appropriately incorporated. Of those, polyarylene ether is particularly excellent in compatibility with the above-mentioned specific polymer and can provide a transparent external appearance when turned into a mixed varnish, and hence is preferred.

The lower limit of the weight-average molecular weight (Mw) of the other polymer is preferably 500, more preferably 800, particularly preferably 1,000. The upper limit of the weight-average molecular weight (Mw) is preferably 50,000, more preferably 30,000, still more preferably 10,000, particularly preferably 6,000. When the weight-average molecular weight (Mw) of the other polymer falls within the above-mentioned ranges, the other polymer is excellent in compatibility with the above-mentioned specific polymer, and hence can provide a transparent external appearance when turned into a mixed varnish.

When the resin composition contains the other polymer, the content of the other polymer in the resin composition is preferably 1 mass % or more, more preferably 3 mass % or more, particularly preferably 5 mass % or more when the total of the specific polymer, the other polymer, and the curable compound is defined as 100 mass %. In addition, the content of the other polymer in the resin composition is preferably 75 mass % or less, more preferably 60 mass % or less, particularly preferably 50 mass % or less when the total of the specific polymer, the other polymer, and the curable compound is defined as 100 mass %.

<Curable Compound>

The curable compound is a compound that is cured by being irradiated with heat or light (e.g., visible light, UV light, a near-infrared ray, a far-infrared ray, or an electron beam), and may be a compound that requires a curing aid to be described later. Examples of such curable compound include an epoxy compound, a cyanate ester compound, a vinyl compound, a silicone compound, an oxazine compound, a maleimide compound, an allyl compound, an acrylic compound, a methacrylic compound, a urethane compound, an oxetane compound, a methylol compound, and a propargyl compound. Those curable compounds may be used alone or in combination thereof. Of those, at least one kind of an epoxy compound, a cyanate ester compound, a vinyl compound, a silicone compound, an oxazine compound, a maleimide compound, and an allyl compound is preferred, and at least one kind of an epoxy compound, a cyanate ester compound, a vinyl compound, an allyl compound, and a maleimide compound is more preferred from the viewpoints of characteristics, such as compatibility with the above-mentioned specific polymer and heat resistance.

Examples of the epoxy compound include compounds represented by the following formulae (c1-1) to (c1-6). The compound represented by the following formula (c1-6) is epoxy group-containing NBR particles “XER-81” manufactured by JSR Corporation. Further examples of the epoxy compound include a polyglycidyl ether of a dicyclopentadiene-phenol polymerized product, a phenol novolac-type liquid epoxy compound, an epoxidized product of a styrene-butadiene block copolymer, and 3′,4′-epoxycyclohexylmethyl-3,4-epoxycyclohexane carboxylate.

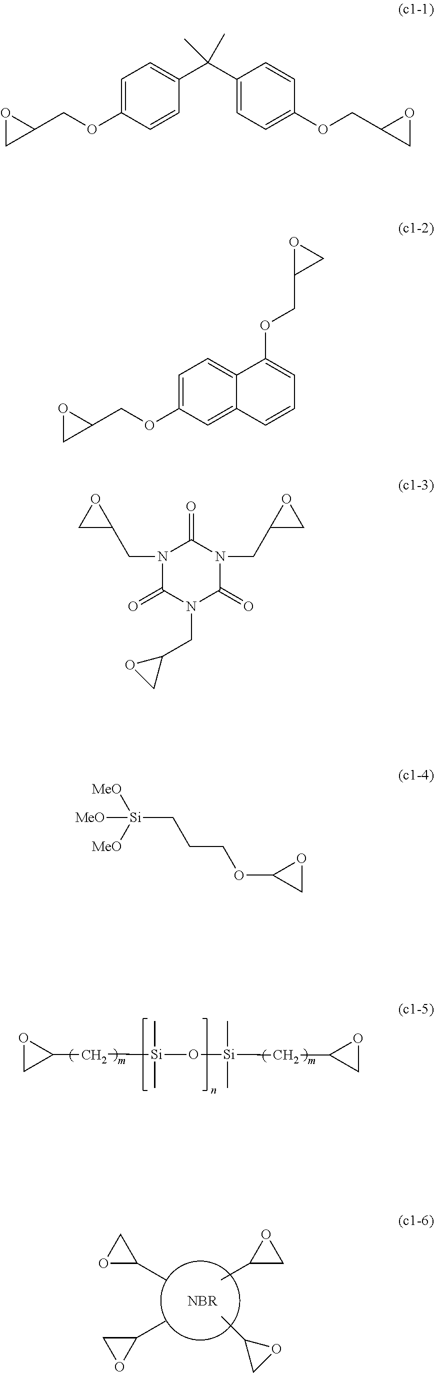

In the formula (c1-5), “n” represents from 0 to 5,000, and “m”s each independently represent from 0 to 5,000.

Examples of the cyanate ester compound include compounds represented by the following formulae (c2-1) to (c2-7).

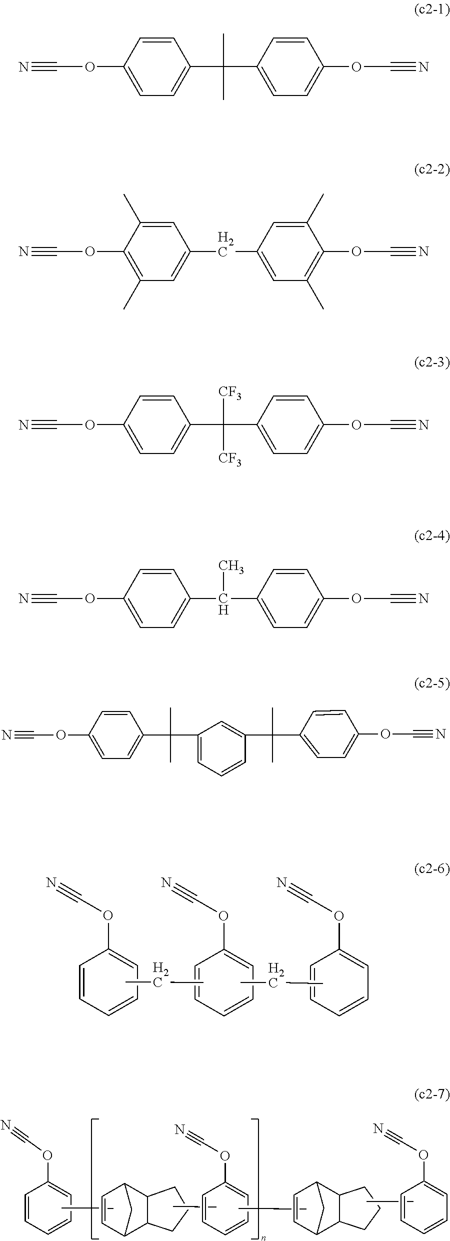

In the formulae (c2-6) and (c2-7), “n”s each independently represent from 0 to 30.

Examples of the vinyl compound include compounds represented by the following formulae (c3-1) to (c3-5).

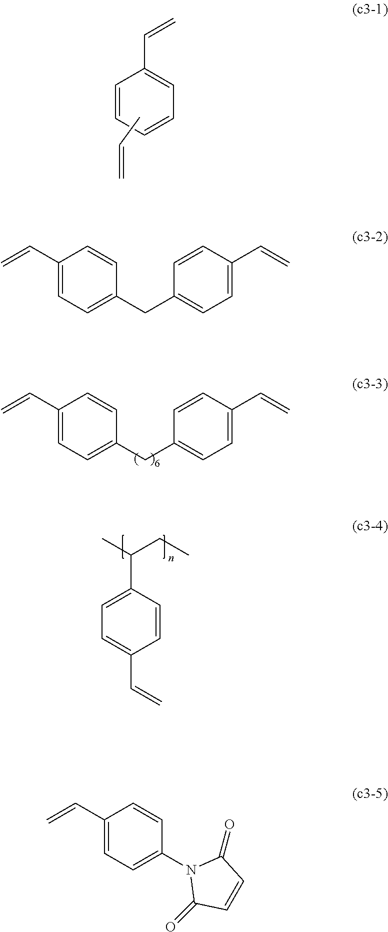

In the formula (c3-4), “n” represents from 1 to 5,000.

Examples of the silicone compound include compounds represented by the following formulae (c4-1) to (c4-16). Any one of the following is selected as R in the formula (c4-1). When a compound having a vinyl group is selected, the compound may be treated as the above-mentioned vinyl compound, and when a compound having an oxetane group is selected, the compound may be treated as the above-mentioned oxetane compound. In addition, in the formulae (c4-2) to (c4-16), Rs each independently represent an organic group selected from an alkyl group, an alicyclic saturated hydrocarbon group, an aryl group, and an alkenyl group, and “n” represents an integer of from 0 to 1,000 (preferably an integer of from 0 to 100).

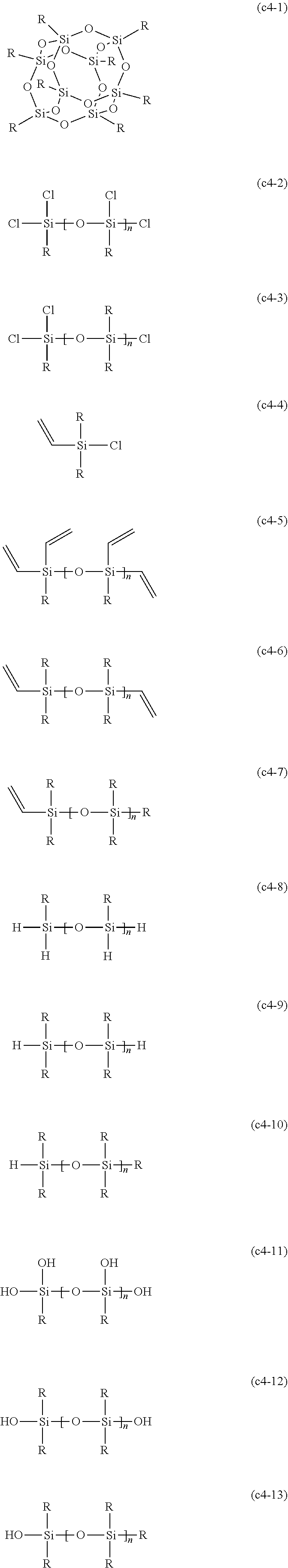

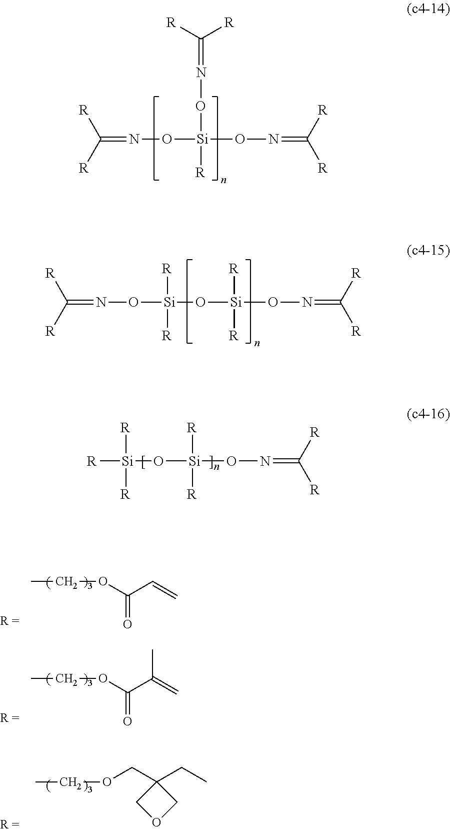

Examples of the oxazine compound include compounds represented by the following formulae (c5-1) to (c5-5).

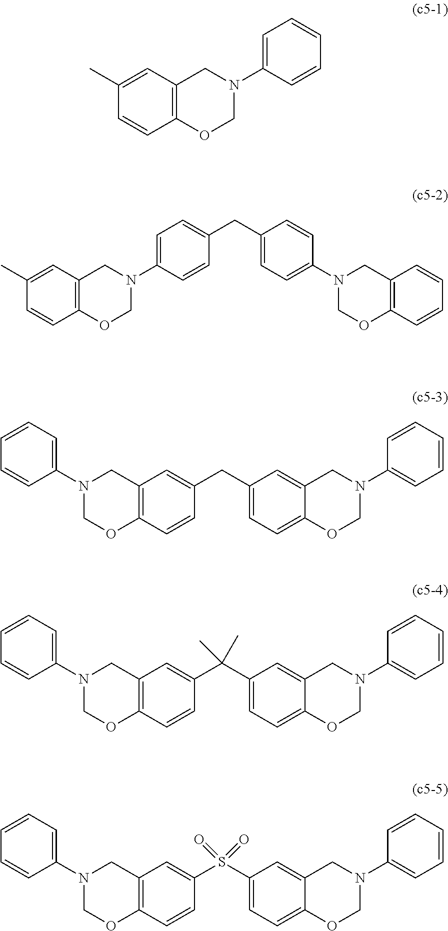 [SMILES: Cc1ccc2c(c1)CN(c1ccccc1)CO2 ; Cc1ccc2c(c1)CN(c1ccc(Cc3ccc(N4COc5ccccc5C4)cc3)cc1)CO2 ; c1ccc(N2COc3ccc(Cc4ccc5c(c4)CN(c4ccccc4)CO5)cc3C2)cc1 ; CC(C)(c1ccc2c(c1)CN(c1ccccc1)CO2)c1ccc2c(c1)CN(c1ccccc1)CO2 ; O=S(=O)(c1ccc2c(c1)CN(c1ccccc1)CO2)c1ccc2c(c1)CN(c1ccccc1)CO2]

Examples of the maleimide compound include compounds represented by the following formulae (c6-1) to (c6-5).

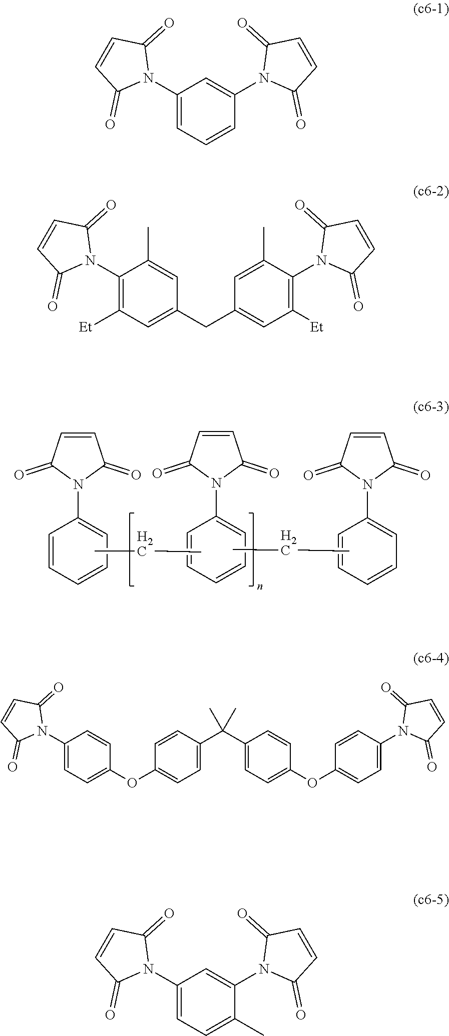

In the formula (c6-2), Et represents an ethyl group, and in the formula (c6-3), “n” represents from 0 to 30.

Examples of the allyl compound include compounds represented by the following formulae (c7-1) to (c7-6). In particular, the allyl compound is preferably a compound having 2 or more (particularly preferably 2 to 6, still more preferably 2 or 3) allyl groups.

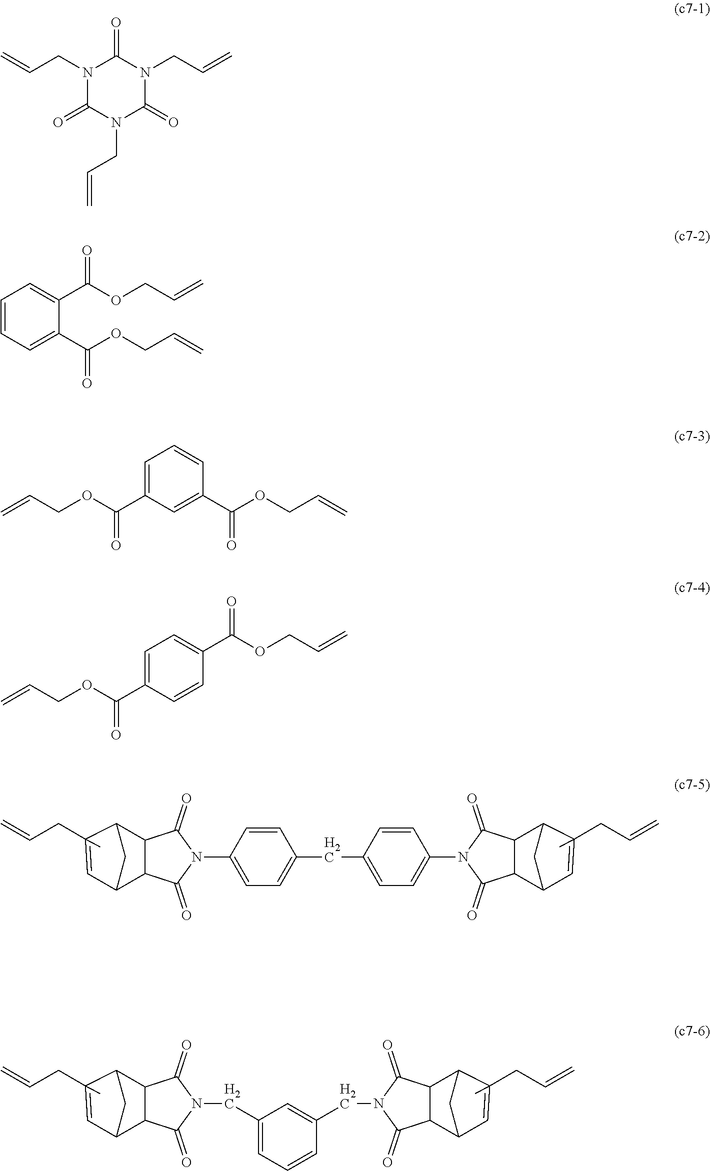

Examples of the oxetane compound include compounds represented by the following formulae (c8-1) to (c8-3).

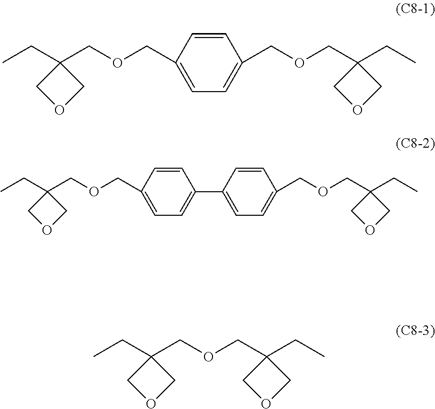

In the formulae (c8-1) and (c8-2), the numbers of repeating units of the parenthesized repeating units are each independently from 0 to 30.

Examples of the methylol compound include methylol compounds described in JP 2006-178059 A and JP 2012-226297 A. Specific examples thereof include: melamine-based methylol compounds, such as polymethylolated melamine, hexamethoxymethylmelamine, hexaethoxymethylmelamine, hexapropoxymethylmelamine, and hexabutoxymethylmelamine; glycoluril-based methylol compounds, such as polymethylolated glycoluril, tetramethoxymethylglycoluril, and tetrabutoxymethylglycoluril; and guanamine-based methylol compounds including compounds each obtained by methylolating guanamine, such as 3,9-bis[2-(3,5-diamino-2,4,6-triazaphenyl)ethyl]-2,4,8,10-tetraoxospiro[5.5]undecane and 3,9-bis[2-(3,5-diamino-2,4,6-triazaphenyl)propyl]-2,4,8,10-tetraoxospiro[5.5]undecane, and compounds obtained by alkyletherifying all or part of active methylol groups in the above-mentioned compounds.

Examples of the propargyl compound include compounds represented by the following formulae (c9-1) and (c9-2).

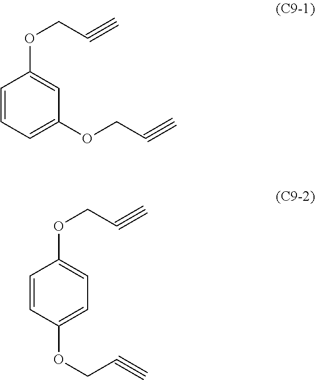

When the resin composition contains the curable compound, the content of the curable compound in the resin composition is preferably 5 mass % or more, more preferably 10 mass % or more, particularly preferably 20 mass % or more when the total of the specific polymer, the other polymer, and the curable compound is defined as 100 mass %. In addition, the content of the curable compound in the resin composition is preferably 75 mass % or less, more preferably 60 mass % or less, particularly preferably 50 mass % or less when the total of the specific polymer, the other polymer, and the curable compound is defined as 100 mass %.

<Curing Aid>

Examples of the curing aid include a radical initiator and polymerization initiators, such as a thermal reaction initiator and a photoreaction initiator (photoradical generator, photoacid generator, or photobase generator).

The radical initiator to be incorporated into the resin composition preferably has a one-minute half-life temperature of 150° C. or more and 190° C. or less. The one-minute half-life temperature of the radical initiator is more preferably 160° C. or more and 190° C. or less, still more preferably 165° C. or more and 190° C. or less, particularly preferably 170° C. or more and 190° C. or less. The term “one-minute half-life temperature” as used herein refers to a temperature at which a period of time required for the radical initiator to decompose to halve its active oxygen amount is 1 minute. The one-minute half-life temperature is a value determined by a method involving dissolving an organic peroxide in a solvent inert to radicals, such as benzene, at a concentration of from 0.05 mol/L to 0.1 mol/L, and thermally decomposing the organic peroxide solution under a nitrogen atmosphere.

When the one-minute half-life temperature of the radical initiator is 150° C. or more, at the time of molding of the resin composition containing the specific polymer under heat and pressure, the specific polymer is sufficiently melted before the crosslinking of a crosslinking-type curable compound is initiated. Accordingly, the resin composition containing such radical initiator is excellent in moldability, and hence is preferred. Meanwhile, when the one-minute half-life temperature of the radical initiator is 190° C. or less, the decomposition rate of the radical initiator under a general condition for the molding under heat and pressure (e.g., a maximum attained temperature of 200° C.) is sufficient, and hence the crosslinking reaction of the crosslinking-type curable compound can be allowed to proceed efficiently and slowly using the radical initiator in a relatively small amount (e.g., ranges described below). Consequently, a satisfactory prepreg having few external appearance defects can be produced.

As such radical initiator, there may be used, for example, 2,5-dimethyl-2,5-di(tert-butylperoxy)hexane, tert-butyl peroxyacetate, di-tert-butyl peroxide, tert-butyl cumyl peroxide, α,α′-bis(tert-butylperoxy-m-isopropyl)benzene, 2,5-dimethyl-2,5-di(tert-butylperoxy)hexane, dicumyl peroxide, tert-butyl peroxybenzoate, 2,2-bis(tert-butylperoxy)butane, and 2,5-dimethyl-2,5-di(benzoylperoxy)hexane. Of those, α,α′-bis(tert-butylperoxy-m-isopropyl)benzene and 2,5-dimethyl-2,5-di(tert-butylperoxy)hexane are preferred from the viewpoint of being able to provide a cured product that is excellent in heat resistance and further has a low dielectric constant and dielectric loss tangent.

Specific examples of the polymerization initiators, such as the thermal reaction initiator and the photoreaction initiator (photoradical generator, photoacid generator, or photobase generator), include an onium salt compound, a sulfone compound, a sulfonic acid ester compound, a sulfonimide compound, a disulfonyldiazomethane compound, a disulfonylmethane compound, an oxime sulfonate compound, a hydrazine sulfonate compound, a triazine compound, a nitrobenzyl compound, a benzylimidazole compound, an organic halide, an octylic acid metal salt, and a disulfone. Those curing aids may be used alone or in combination thereof irrespective of the types thereof. In addition, the polymerization initiators may each be used in combination with the radical initiator.

When the resin composition contains the epoxy compound as the curable compound, for example, an amine-based curing agent, an acid or acid anhydride-based curing agent, a basic active hydrogen compound, an imidazole, a polymercaptan-based curing agent, a phenol resin, a urea resin, a melamine resin, an isocyanate-based curing agent, or a Lewis acid may be used as the curing aid.

Examples of the amine-based curing agent include: polyamines, such as ethylenediamine, diethylenetriamine, triethylenetetramine, tetraethylenepentamine, hexamethylenediamine, iminobispropylamine, bis(hexamethylene)triamine, and 1,3,6-trisaminomethylhexane; cyclic aliphatic polyamines, such as menthenediamine (MDA), isophoronediamine (IPDA), bis(4-amino-3-methylcyclohexyl)methane, diaminodicyclohexylmethane, bisaminomethylcyclohexane, 3,9-bis(3-aminopropyl)-2,4,8,10-tetraoxaspiro[5.5]undecane, and a diamine having a norbornane skeleton, typified by NBDA manufactured by Mitsui Chemicals, Inc.; aliphatic polyamines each having an aromatic ring, such as m-xylylenediamine (MXDA); and aromatic polyamines, such as m-phenylenediamine, diaminodiphenylmethane, diaminodiphenyl sulfone, and diaminodiethyldiphenylmethane, and derivatives thereof.

Further, other examples of the amine-based curing agent include: a Mannich-modified amine obtained by subjecting a polyamine to a reaction with an aldehyde and/or a phenol; an amine adduct (polyamine epoxy resin adduct), a polyamine-ethylene oxide adduct, a polyamine-propylene oxide adduct, a cyanoethylated polyamine, and a ketimine, which is a product of a reaction between an aliphatic polyamine and a ketone; secondary amines or tertiary amines, such as tetramethylguanidine, triethanolamine, piperidine, pyridine, benzyldimethylamine, picoline, 2-(dimethylaminomethyl)phenol, dimethylcyclohexylamine, dimethylbenzylamine, dimethylhexylamine, dimethylaminophenol, dimethylamino-p-cresol, N,N′-dimethylpiperazine, 1,4-diazabicyclo[2.2.2]octane, 2,4,6-tris(dimethylaminomethyl)phenol, and 1,8-diazabicyclo[5.4.0]-7-undecene; and a liquid polyamide obtained by subjecting a dimer acid to a reaction with a polyamine, such as diethylenetriamine or triethylenetetramine.

Examples of the acid or acid anhydride-based curing agent include: polycarboxylic acids, such as adipic acid, azelaic acid, and decanedicarboxylic acid; aromatic acid anhydrides, such as phthalic anhydride, trimellitic anhydride, ethylene glycol bis(anhydrotrimellitate), glycerol tris(anhydrotrimellitate), pyromellitic anhydride, and 3,3′,4,4′-benzophenonetetracarboxylic anhydride; cyclic aliphatic acid anhydrides, such as maleic anhydride, succinic anhydride, tetrahydrophthalic anhydride, methyltetrahydrophthalic anhydride, methylnadic anhydride, an alkenylsuccinic anhydride, hexahydrophthalic anhydride, methylhexahydrophthalic anhydride, methylcyclohexene tetracarboxylic anhydride, methyl himic anhydride, a trialkyl tetrahydrophthalic anhydride, and poly(phenylhexadecanedioic) anhydride; aliphatic acid anhydrides, such as polyadipic anhydride, polyazelaic anhydride, polysebacic anhydride, dodecenylsuccinic anhydride, and poly(ethyloctadecanedioic) anhydride; and halogenated acid anhydrides, such as chlorendic anhydride, tetrabromophthalic anhydride, and het anhydride.

Examples of the basic active hydrogen compound include dicyandiamide and organic acid dihydrazides.

Examples of the imidazole include 2-methylimidazole, 2-ethyl-4-methylimidazole, 2-undecylimidazole, 2-heptadecylimidazole, 2-phenylimidazole, 1-benzyl-2-methylimidazole, 1-cyanoethyl-2-methylimidazole, 1-cyanoethyl-2-ethyl-4-methylimidazole, 2-methylimidazolium isocyanurate, 2,4-diamino-6-[2-methylimidazoline-(1)]-ethyl-S-triazine, and 2,4-diamino-6-[2-ethyl-4-methylimidazoline-(1)]-ethyl-S-triazine.

Examples of the polymercaptan-based curing agent include: partial epoxy adducts of 2,2′-bismercaptoethyl ether; thioglycolic acid esters, such as pentaerythritol tetrathioglycolate, dipentaerythritol hexathioglycolate, and trimethylolpropane tristhioglycolate; and compounds each having a mercapto group, such as a polysulfide rubber having a mercapto group at an end thereof.

Examples of the isocyanate-based curing agent include: isocyanate compounds, such as toluene diisocyanate, hexamethylene diisocyanate, and xylene diisocyanate; and blocked isocyanate compounds each obtained by subjecting an isocyanate group to a reaction with a blocking agent, such as phenol, an alcohol, or a caprolactam, to mask the isocyanate group.

Examples of the Lewis acid include a diaryliodonium salt and a triarylsulfonium salt.

In addition, when the resin composition contains the epoxy compound as the curable compound, photoacid generators, such as an onium salt compound, a sulfone compound, a sulfonic acid ester compound, a sulfonimide compound, a disulfonyl diazomethane compound, a disulfonyl methane compound, an oxime sulfonate compound, a hydrazine sulfonate compound, a triazine compound, a nitrobenzyl compound, an organic halide, and a disulfone, may each be used as the curing aid.

Further, when the resin composition contains the epoxy compound as the curable compound, photobase generators, such as (Z)-{[bis(dimethylamino)methylidene]amino}-N-cyclohexyl(cyclohexylamino)methaniminium tetrakis(3-fluorophenyl)borate, 1,2-dicyclohexyi-4,4,5,5-tetramethylbiguanidium n-butyltriphenylborate, 9-anthrylmethyl N,N-diethylcarbamate, (E)-1-[3-(2-hydroxyphenyl)-2-propenoyl]piperidine, 1-(anthraquinon-2-yl)ethyl imidazolecarboxylate, 2-nitrophenylmethyl-4-methacryloyloxypiperidine-1-carboxylate, and 1,2-diisopropyl-3-[bis(dimethylamino)methylene]guanidium 2-(3-benzoylphenyl)propionate, may each be used as the curing aid.

When the resin composition contains the cyanate ester compound as the curable compound, an organic metal salt, such as zinc octylate, zinc naphthenate, cobalt naphthenate, copper naphthenate, iron acetylacetonate, nickel octylate, or manganese octylate, a phenol compound, such as phenol, xylenol, cresol, resorcin, catechol, octylphenol, or nonylphenol, an alcohol, such as 1-butanol or 2-ethylhexanol, an imidazole, such as 2-methylimidazole, 2-ethyl-4-methylimidazole, 2-phenylimidazole, 1-benzyl-2-methylimidazole, 1-cyanoethyl-2-phenylimidazole, 1-cyanoethyl-2-ethyl-4-methylimidazole, 2-phenyl-4,5-dihydroxymethylimidazole, or 2-phenyl-4-methyl-5-hydroxymethylimidazole, and a derivative thereof, such as an adduct of any of those imidazoles with a carboxylic acid or an acid anhydride thereof, an amine, such as benzyldimethylamine or 4-methyl-N,N-dimethylbenzylamine, and a phosphorus compound, such as a phosphine-based compound or a phosphine oxide-based compound, may each be used as the curing aid. Further, the photoacid generator or the photobase generator, which has been described as the curing aid in the case where the resin composition contains the epoxy compound, may be used.

When the resin composition contains the vinyl compound as the curable compound, a compound (polymerization agent) that generates a cationic or radical active species with heat or light may be used as the curing aid. Examples of the cationic polymerization agent include a diaryliodonium salt and a triarylsulfonium salt. Examples of the radical polymerization agent include: benzoin-based compounds such as benzoin acetophenone; acetophenone-based compounds such as 2,2-dimethoxy-2-phenylacetophenone; sulfur-based compounds such as 2,4-diethylthioxanthone; azo compounds such as azobisisobutyronitrile; and organic peroxides, such as 2,5-dimethyl-2,5-di(tert-butylperoxy)hexane and dicumyl peroxide.

In addition, when the resin composition contains the vinyl compound as the curable compound, photoradical generators, such as acetophenone, propiophenone, benzophenone, xanthol, benzaldehyde, anthraquinone, triphenylamine, carbazole, 3-methylacetophenone, 4-methylacetophenone, 3-pentylacetophenone, 4-methoxyacetophenone, 3-bromoacetophenone, 4-allylacetophenone, p-diacetylbenzene, 3-methoxybenzophenone, 4-methylbenzophenone, 4-chlorobenzophenone, 4,4′-dimethoxybenzophenone, 4-chloro-4′-benzylbenzophenone, 3-chloroxanthone, 3,9-dichloroxanthone, 3-chloro-8-nonylxanthone, benzoin, benzoin methyl ether, benzoin butyl ether, bis(4-dimethylaminophenyl) ketone, benzyl methoxy ketal, and 2-chlorothioxanthone, may each be used as the curing aid.

When the resin composition contains the silicone compound as the curable compound, platinum group metal catalysts including: platinum-based catalysts, such as platinum black, platinic chloride, chloroplatinic acid, a product of a reaction between chloroplatinic acid and a monohydric alcohol, a complex of chloroplatinic acid and an olefin, and platinum bisacetoacetate; palladium-based catalysts; and rhodium-based catalysts, zinc benzoate, and zinc octylate may each be used as the curing aid.

In addition, when the resin composition contains the silicone compound as the curable compound, for example, phenol and derivatives thereof, cyanic acid esters, Brønsted acids such as p-toluenesulfonic acid, adipic acid, p-toluenesulfonic acid esters, aromatic amine compounds, such as 4,4′-diaminodiphenyl sulfone and melamine, bases such as 2-ethyl-4-methylimidazole, and Lewis acids such as boron trifluoride may each be used as the curing aid. Further, the photoacid generator or the photobase generator described as the curing aid in the case where the resin composition contains the epoxy compound may be used.

When the resin composition contains the maleimide compound as the curable compound, for example, bases, such as imidazole, 1-methylimidazole, 1-benzyl-2-methylimidazole, 2-methylimidazoline, N,N-diisopropylethylamine, 1,4-dimethylpiperazine, quinoline, triazole, benzotriazole, and DBU, phosphorus compounds such as triphenylphosphine, and azobisisobutyronitrile may each be used as the curing aid. Further, the photoacid generator or the photobase generator described as the curing aid in the case where the resin composition contains the epoxy compound may be used.

When the resin composition contains the allyl compound or the propargyl compound as the curable compound, curing aids including: azo initiators, such as azobisisobutyronitrile and dimethyl 2,2′-azobisisobutyrate; peroxides, such as a ketone peroxide, a peroxyketal, a hydroperoxide, a dialkyl peroxide, a diacyl peroxide, a peroxydicarbonate, and a peroxyester; acetophenone-based curing aids such as 2-methyl-1-[4-(methylthio)phenyl]-2-morpholinopropane-1,1′-hydroxycyclohexyl phenyl ketone; benzoin-based curing aids, such as benzoin and benzoin ethyl ether; benzophenone-based curing aids such as benzophenone; phosphorus-based curing aids such as an acyl phosphine oxide; sulfur-based curing aids such as thioxanthone; benzil-based curing aids, such as benzil and 9,10-phenanthrenequinone; and peroxycarbonate-based curing aids may each be used as the curing aid. Further, the photoacid generator or the photobase generator described as the curing aid in the case where the resin composition contains the epoxy compound may be used.

When the resin composition contains the oxetane compound or the methylol compound as the curable compound, a photocation generator or a thermal cation generator may be used as the curing aid.

Examples of the photocation generator include an onium salt compound, a halogen-containing compound, a sulfone compound, a sulfonic acid compound, a sulfonimide compound, and a diazomethane compound. Specific examples thereof include compounds described in paragraphs [0074] to [0079] of JP 2014-186300 A.

Examples of the halogen-containing compound include a haloalkyl group-containing hydrocarbon compound and a haloalkyl group-containing heterocyclic compound. Preferred specific examples of the halogen-containing compound include: 1,10-dibromo-n-decane; 1,1-bis(4-chlorophenyl)-2,2,2-trichloroethane; and s-triazine derivatives, such as phenyl-bis(trichloromethyl)-s-triazine, 4-methoxyphenyl-bis(trichloromethyl)-s-triazine, styryl-bis(trichloromethyl)-s-triazine, naphthyl-bis(trichloromethyl)-s-triazine, and 2-[2-(5-methylfuran-2-yl)ethenyl]-4,6-bis-(trichloromethyl)-1,3,5-triazine.

Examples of the thermal cation generator include benzyl(4-hydroxyphenyl)(methyl)sulfonium tetrakis(pentafluorophenyl)borate, (4-hydroxyphenyl)(dimethyl)sulfonium tetrakis(pentafluorophenyl)borate, 4-acetoxyphenyl(dimethyl)sulfonium tetrakis(pentafluorophenyl)borate, (4-hydroxyphenyl)methyl(4-methylbenzyl)sulfonium tetrakis(pentafluorophenyl)borate, and benzyl(4-hydroxyphenyl)(methyl)sulfonium hexafluorophosphate.

When the resin composition contains the curing aid, the content of the curing aid preferably falls within a range in which the resin composition satisfactorily cures to provide a cured product. A specific content of the curing aid is preferably from 0.5 mass % to 20 mass %, more preferably from 1 mass % to 10 mass % when the total mass of the resin composition is defined as 100 mass %.

<Flame Retardant>

The resin composition preferably contains a flame retardant. Examples of the flame retardant include: inorganic flame retardants, such as antimony trioxide, aluminum hydroxide, magnesium hydroxide, and zinc borate; aromatic bromine compounds, such as hexabromobenzene, decabromodiphenylethane, 4,4-dibromobiphenyl, and ethylenebistetrabromophthalimide; phosphorus-based compounds, such as resorcinol bis-diphenyl phosphate and resorcinol bis-dixylenyl phosphate; and phenoxyphosphazene-based flame retardants, such as hexaphenoxycyclotriphosphazene, cyanophenoxy(phenoxy)cyclotriphosphazene, and cresoyloxy(phenoxy)cyclotriphosphazene. Those flame retardants are used alone or in combination thereof. Of those, an inorganic flame retardant or a halogen-free, phosphorus-based or phosphazene-based compound is preferred as the flame retardant from the viewpoint of being further excellent in reliability and low dielectric characteristics after the curing of the resin composition.

When the resin composition contains the flame retardant, the content of the flame retardant in the resin composition is preferably 5 parts by mass or more, more preferably 10 parts by mass or more, particularly preferably 15 parts by mass or more with respect to 100 parts by mass of the total of the specific polymer, the other polymer, and the curable compound from the viewpoint of maintaining flame retardancy at the V-0 level according to LTL Standard 94. In addition, the content of the flame retardant in the resin composition is preferably 50 parts by mass or less, more preferably 45 parts by mass or less, particularly preferably 40 parts by mass or less with respect to 100 parts by mass of the total of the specific polymer, the other polymer, and the curable compound from the viewpoint that the dielectric constant and dielectric loss tangent of a printed wiring board to be obtained can be kept low.

<Inorganic Filler>

The resin composition may contain an inorganic filler. As a material for the inorganic filler, there are given, for example, silica, alumina, silicon nitride, boron nitride, and aluminum nitride. Examples of the silica include natural silica, molten silica, synthetic silica, amorphous silica, aerosil, and hollow silica. In addition, the silica may have its surface subjected to surface treatment with a silane coupling agent or the like.

When the resin composition contains the inorganic filler, the content of the inorganic filler is preferably from 10 parts by mass to 200 parts by mass with respect to 100 parts by mass of the total of the specific polymer, the other polymer, and the curable compound.

<Solvent>

The resin composition may contain a solvent. In this case, the resin composition may have the form of a varnish in which its solid content is dissolved or dispersed in the solvent. The above-mentioned specific polymer has satisfactory solubility in various solvents irrespective of the magnitude of its weight-average molecular weight, and hence a variety of solvents may be used.

Examples of the solvent include: amide-based solvents, such as N,N-dimethylacetamide, N,N-dimethylformamide, N-methyl-2-pyrrolidone, N-ethyl-2-pyrrolidone, and 1,3-dimethyl-2-imidazolidinone; ester-based solvents, such as γ-butyrolactone and butyl acetate; ketone-based solvents, such as cyclopentanone, cyclohexanone, methyl ethyl ketone, benzophenone, and 2-heptanone; ether-based solvents, such as 1,2-methoxyethane and diphenyl ether; polyfunctional solvents, such as 1-methoxy-2-propanol and propylene glycol methyl ether acetate; sulfone-based solvents, such as sulfolane, dimethyl sulfoxide, diethyl sulfoxide, dimethyl sulfone, diethyl sulfone, diisopropyl sulfone, and diphenyl sulfone; aromatic solvents, such as benzene, toluene, xylene, mesitylene, dialkoxybenzenes (having alkoxy groups each having 1 to 4 carbon atoms), trialkoxybenzenes (having alkoxy groups each having 1 to 4 carbon atoms), and benzoic acid esters; and haloalkanes, such as methylene chloride and chloroform. Those solvents may be used alone or in combination thereof. Of those, the following solvents are preferred from the viewpoint of solubility: aromatic solvents, such as toluene, xylene, and mesitylene; ketone-based solvents, such as methyl ethyl ketone, cyclopentanone, cyclohexanone, and 2-heptanone; amide-based solvents, such as N,N-dimethylacetamide and N-methyl-2-pyrrolidone; and chloroform.

When the resin composition contains the solvent, the content of the solvent is preferably 2,000 parts by mass or less, more preferably 200 parts by mass or less with respect to 100 parts by mass of the resin composition excluding the solvent.

<Other Additive>

The resin composition may contain an additive, such as a heat stabilizer, an antioxidant, a UV absorber, a surfactant, or a lubricant, as required.

### 3. METAL-CLAD LAMINATE

A metal-clad laminate according to one embodiment of the present invention is obtained by laminating the above-mentioned prepreg and metal foil, followed by curing. The metal-clad laminate preferably has such a form that a cured product of the prepreg (sometimes referred to as “cured product composite”) and the metal foil are laminated to adhere to each other, and is suitably used as a material for an electronic substrate. Examples of the metal foil include aluminum foil and copper foil. Of those, copper foil is preferred because its electric resistance is low. One or a plurality of the cured product composites may be combined with the metal foil, and in accordance with an application, the metal foil is overlaid on one surface or both surfaces of the cured product composite, and the resultant is processed into a laminate. As a method of producing the laminate, there is given, for example, a method involving: forming a composite (e.g., the above-mentioned prepreg) including a thermally curable resin composition and a base material; overlaying the composite and metal foil on each other; and then curing the thermally curable resin composition, to thereby obtain a laminate in which a cured product laminated body and the metal foil are laminated. One of the particularly preferred applications of the laminate is a printed wiring board. The printed wiring board preferably includes the metal-clad laminate from which at least part of the metal foil has been removed.

### 4. PRINTED WIRING BOARD

A printed wiring board according to one embodiment of the present invention includes a metal-clad laminate from which part of its metal foil has been removed. The printed wiring board according to this embodiment may be typically formed by a method involving performing molding under pressure and heat using the prepreg of the present invention described above. A base material is, for example, the same base material as described above for the prepreg. By virtue of containing the above-mentioned specific polymer, the printed wiring board according to this embodiment has excellent heat resistance and electric characteristics (low dielectric constant and low dielectric loss tangent), can reduce fluctuations in electric characteristics caused by environmental fluctuations, and also has excellent insulation reliability and mechanical characteristics.

### 5. EXAMPLES

The above-mentioned embodiments are specifically described below by way of Examples. However, the embodiments are by no means limited by the following Examples. The terms “part(s)” and “%” in the following are on a mass basis unless otherwise stated.

5.1. Physical Property Measurement

Physical properties described in Examples and Comparative Examples below were evaluated by the following measurement methods.

(1) Weight-Average Molecular Weight (Mw) of Polymer

A weight-average molecular weight (Mw) was measured with a GPC apparatus (“HLC-8320” from Tosoh Corporation) under the following conditions.

### (Measurement Conditions)

Column: column obtained by connecting “TSKgel α-M” manufactured by Tosoh Corporation and “TSKgel Guard Column α” manufactured by Tosob Corporation
Developing solvent: N-methyl-2-pyrrolidone
Column temperature: 40° C.
Flow rate: 1.0 mL/min
Sample concentration: 0.75 mass %
Sample injection amount: 50 IL
Detector: differential refractometer
Standard substance: monodispersed polystyrene

(2) Glass Transition Temperature (Tg) of Polymer

A glass transition temperature (Tg) was measured with a dynamic viscoelasticity measurement apparatus (manufactured by Seiko Instruments Inc., “DMS7100”) at a frequency of 1 Hz and a rate of temperature increase of 10° C./min, and was defined as a temperature at which a loss tangent became maximum. The loss tangent was defined as a value obtained by dividing a storage elastic modulus by a loss elastic modulus.

(3) Dielectric Constant and Dielectric Loss Tangent of Laminate and Glass Sample

The dielectric constant and dielectric loss tangent of each of a laminate and a glass sample at 1 GHz were measured by a cavity resonance method. A network analyzer (N5230A, manufactured by Agilent Technologies, Inc.) and a cavity resonator manufactured by Kanto Electronic Application and Development Inc. (Cavity Resornator CP431) were used as measurement apparatus. A laminate or glass sample having a thickness of about 0.5 mm was cut into a size measuring about 2 mm wide by 80 mm long in such a manner that, in the case of the laminate, the warp of its glass cloth was a long side, to thereby prepare two identical samples. Next, the two samples were placed in an oven at 105° C. 2° C. and dried for 2 hours, and were then left at rest, one of the samples being placed under an environment at 23° C. and a relative humidity of 50±5%, and the other sample being placed under an environment at 40° C. and a relative humidity of 85±5%, for 96±5 hours. After that, the two samples were each measured for its dielectric constant and dielectric loss tangent under an environment at 23° C. and a relative humidity 50±5% through use of the above-mentioned measurement apparatus.

5.2. Synthesis of Polymer

### Synthesis Example 1

1,1-Bis(4-hydroxyphenyl)-3,3,5-trimethyicyclohexane (BisTMC) (18.6 g, 60.0 mmol), 4,6-dichloropyrimidine (Pym) (8.5 g, 57.6 mmol), and potassium carbonate (11.1 g, 81.0 mmol) were weighed in a four-necked separable flask with a stirring device. N-Methyl-2-pyrrolidone (64 g) was added, and the whole was subjected to a reaction under a nitrogen atmosphere at 130° C. for 8 hours. After the completion of the reaction, N-methyl-2-pyrrolidone (368 g) was added, and a salt was removed by filtration. After that, the remaining solution was charged into methanol (9.1 kg). A precipitated solid was separated by filtration and washed with a small amount of methanol. The solid was separated by filtration again and recovered, and was then dried with a vacuum dryer under reduced pressure at 120° C. for 12 hours to provide a polymer P-1 having a structural unit represented by the following formula (P-1) (yield; 20.5 g, percent yield; 90%, weight-average molecular weight (Mw); 28,000, glass transition temperature (Tg); 206° C.).

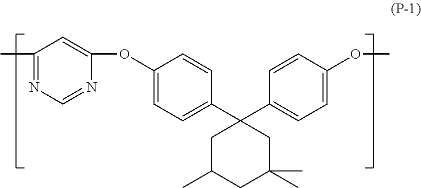

### Synthesis Example 2

1,1-Bis(4-hydroxyphenyl)-3,3,5-trimethylcyclohexane (BisTMC) (18.6 g, 60.0 mmol) and 4,6-dichloropyrimidine (Pym) (7.7 g, 52.2 mmol) were used and subjected to a reaction in accordance with Synthesis Example 1 to provide a polymer P-2 having a weight-average molecular weight (Mw) of 7,000.

### Synthesis Example 3

1,1-Bis(4-hydroxyphenyl)-3,3,5-trimethylcyclohexane (BisTMC) (18.6 g, 60.0 mmol) and 4,6-dichloropyrimidine (Pym) (8.9 g, 60.0 mmol) were used and subjected to a reaction in accordance with Synthesis Example 1 to provide a polymer P-3 having a weight-average molecular weight (Mw) of 90,000.

### Synthesis Example 4

1,1-Bis(4-hydroxyphenyl)-3,3,5-trimethylcyclohexane (BisTMC) (10.7 g, 34.5 mmol), 3,6-dichloropyridazine (Pyd) (5.1 g, 34.2 mmol), and potassium carbonate (6.5 g, 47.0 mmol) were weighed in a four-necked separable flask with a stirring device. N-Methyl-2-pyrrolidone (36 g) was added, and the whole was subjected to a reaction under a nitrogen atmosphere at 145° C. for 9 hours. After the completion of the reaction, N-methyl-2-pyrrolidone (150 g) was added for dilution, and a salt was removed by filtration. After that, the remaining solution was charged into methanol (3 kg). A precipitated solid was separated by filtration and washed with a small amount of methanol. The solid was separated by filtration again and recovered, and was then dried under the same conditions as those of Synthesis Example 1 to provide a polymer P-4 having a structural unit represented by the following formula (P-4) (yield; 7.6 g, percent yield; 48%, weight-average molecular weight (Mw); 30,000, glass transition temperature (Tg); 232° C.). The weight-average molecular weight and the glass transition temperature were measured in the same manner as in Synthesis Example.

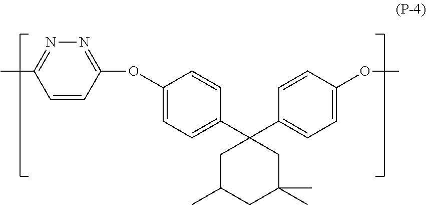

### Synthesis Example 5

1,1-Bis(4-hydroxyphenyl)-3,3,5-trimethylcyclohexane (BisTMC) (18.6 g, 60.0 mmol), 4,6-dichloro-2-phenylpyrimidine (PhPym) (13.7 g, 61.1 mmol), and potassium carbonate (11.4 g, 82.5 mmol) were weighed in a four-necked separable flask with a stirring device. N-Methyl-2-pyrrolidone (75 g) was added, and the whole was subjected to a reaction under a nitrogen atmosphere at 130° C. for 6 hours. After the completion of the reaction, N-methyl-2-pyrrolidone (368 g) was added for dilution, and a salt was removed by filtration. After that, the remaining solution was charged into methanol (9.1 kg). A precipitated solid was separated by filtration and washed with a small amount of methanol. The solid was separated by filtration again and recovered, and was then dried under the same conditions as those of Synthesis Example 1 to provide a polymer P-5 having a structural unit represented by the following formula (P-5) (yield; 20.5 g, percent yield; 90%, weight-average molecular weight (Mw); 187,000, glass transition temperature (Tg); 223° C.). The weight-average molecular weight and the glass transition temperature were measured in the same manner as in Synthesis Example 1.

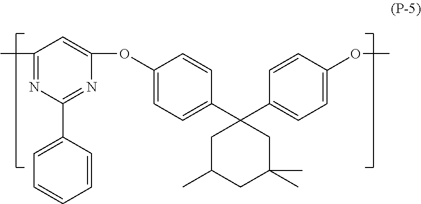

### Synthesis Example 6

1,1-Bis(4-hydroxyphenyl)-3,3,5-trimethyleyclohexane (BisTMC) (12.4 g, 40.0 mmol), 2,2-bis(4-hydroxyphenyl)-propane (BisA) (2.3 g, 10.0 mmol), 1,1-bis(4-hydroxyphenyl)-nonane (BisP-DED) (3.3 g, 10.0 mmol), 4,6-dichloro-2-phenylpyrimidine (PhPyn) (13.7 g, 61.1 mmol), and potassium carbonate (11.4 g, 82.5 mmol) were weighed in a four-necked separable flask with a stirring device. N-Methyl-2-pyrrolidone (75 g) was added, and the whole was subjected to a reaction under a nitrogen atmosphere at 130° C. for 6 hours. After the completion of the reaction, N-methyl-2-pyrrolidone (368 g) was added for dilution, and a salt was removed by filtration. After that, the remaining solution was charged into methanol (9.1 kg). A precipitated solid was separated by filtration and washed with a small amount of methanol. The solid was separated by filtration again and recovered, and was then dried under the same conditions as those of Synthesis Example 1 to provide a polymer P-6 having a structural unit represented by the following formula (P-6) (yield; 23.5 g, percent yield; 87%, weight-average molecular weight (Mw); 165,000, glass transition temperature (Tg); 196° C.). The weight-average molecular weight and the glass transition temperature were measured in the same manner as in Synthesis Example 1.

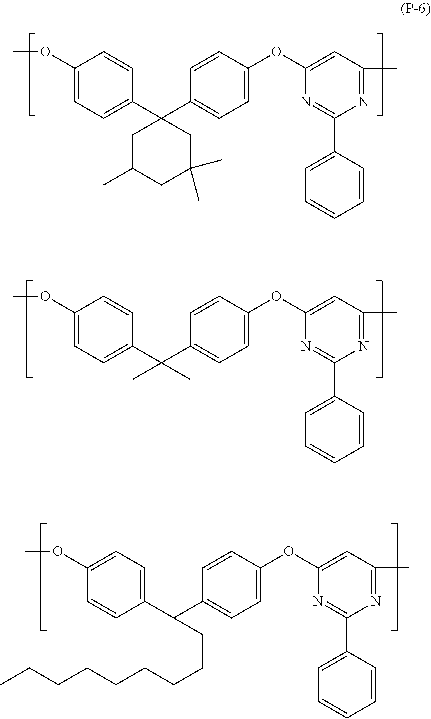

### Synthesis Example 7

1,1-Bis(4-hydroxyphenyl)-3,3,5-trimethyicyclohexane (BisTMC) (12.4 g, 40.0 mmol), 4,4′-(1,3-dimethylbutylidene)bisphenol (BisP-MIBK) (2.7 g, 10.0 mmol), 1,1-bis(4-hydroxyphenyl)-nonane (BisP-DED) (3.3 g, 10.0 mmol), 4,6-dichloro-2-phenylpyrimidine (PhPym) (13.7 g, 61.1 mmol), and potassium carbonate (11.4 g, 82.5 mmol) were weighed in a four-necked separable flask with a stirring device. N-Methyl-2-pyrrolidone (75 g) was added, and the whole was subjected to a reaction under a nitrogen atmosphere at 130° C. for 6 hours. After the completion of the reaction, N-methyl-2-pyrrolidone (368 g) was added for dilution, and a salt was removed by filtration. After that, the remaining solution was charged into methanol (9.1 kg). A precipitated solid was separated by filtration and washed with a small amount of methanol The solid was separated by filtration again and recovered, and was then dried under the same conditions as those of Synthesis Example 1 to provide a polymer P-7 having a structural unit represented by the following formula (P-7) (yield; 23.8 g, percent yield; 88%, weight-average molecular weight (Mw); 157,000, glass transition temperature (Tg); 190° C.). The weight-average molecular weight and the glass transition temperature were measured in the same manner as in Synthesis Example 1.

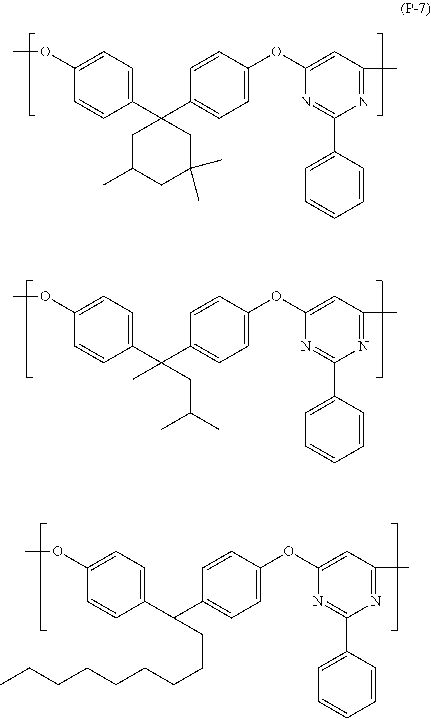

### Synthesis Example 8

2,2′-Bis(4-hydroxyphenyl)propane (BisA) (13.7 g, 60.0 mmol), 4,6-dichloropyrimidine (Pym) (8.5 g, 57.6 mmol), and potassium carbonate (11.1 g, 81.0 mmol) were weighed in a four-necked separable flask with a stirring device. N-Methyl-2-pyrrolidone (64 g) was added, and the whole was subjected to a reaction under a nitrogen atmosphere at 130° C. for 8 hours. After the completion of the reaction, N-methyl-2-pyrrolidone (368 g) was added, and a salt was removed by filtration. After that, the remaining solution was charged into methanol (9.1 kg). A precipitated solid was separated by filtration and washed with a small amount of methanol. The solid was separated by filtration again and recovered, and was then dried with a vacuum dryer under reduced pressure at 120° C. for 12 hours to provide a polymer P-8 having a structural unit represented by the following formula (P-8) (yield; 16.5 g, percent yield; 90%, weight-average molecular weight (Mw); 25,000, glass transition temperature (Tg); 156° C.).

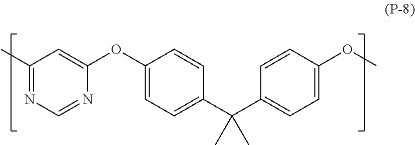

### Synthesis Example 9

2,2′-Bis(3-methyl-4-hydroxyphenyl)propane (BisC) (15.4 g, 60.0 mmol), 4,6-dichloropyrimidine (Pym) (7.7 g, 52.2 mmol), and potassium carbonate (11.1 g, 81.0 mmol) were weighed in a four-necked separable flask with a stirring device. N-Methyl-2-pyrrolidone (64 g) was added, and the whole was subjected to a reaction under a nitrogen atmosphere at 130° C. for 8 hours. After the completion of the reaction, N-methyl-2-pyrrolidone (368 g) was added, and a salt was removed by filtration. After that, the remaining solution was charged into methanol (9.1 kg). A precipitated solid was separated by filtration and washed with a small amount of methanol. The solid was separated by filtration again and recovered, and was then dried with a vacuum dryer under reduced pressure at 120° C. for 12 hours to provide a polymer P-9 having a structural unit represented by the following formula (P-9) (yield; 17.0 g, percent yield; 85%, weight-average molecular weight (Mw); 65,000, glass transition temperature (Tg); 130° C.).

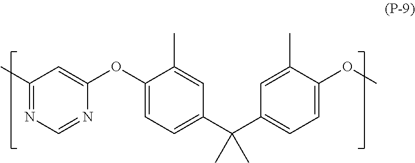

### Synthesis Example 10

4,4′-(1,3-Phenylenebis(propane-2,2-diyl))diphenol (BisM) (20.8 g, 60.0 mmol), 4,6-dichloropyrimidine (Pym) (8.5 g, 57.6 mmol), and potassium carbonate (11.1 g, 81.0 mmol) were weighed in a four-necked separable flask with a stirring device. N-Methyl-2-pyrrolidone (64 g) was added, and the whole was subjected to a reaction under a nitrogen atmosphere at 130° C. for 8 hours. After the completion of the reaction, N-methyl-2-pyrrolidone (368 g) was added, and a salt was removed by filtration. After that, the remaining solution was charged into methanol (9.1 kg). A precipitated solid was separated by filtration and washed with a small amount of methanol. The solid was separated by filtration again and recovered, and was then dried with a vacuum dryer under reduced pressure at 120° C. for 12 hours to provide a polymer P-10 having a structural unit represented by the following formula (P-10) (yield; 22.1 g, percent yield; 87%, weight-average molecular weight (Mw); 25,000, glass transition temperature (Tg); 112° C.).

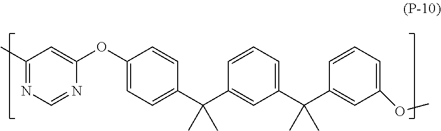

### Synthesis Example 11

4,4′-(1,4-Phenylenebis(propane-2,2-diyl))diphenol (BisP) (20.8 g, 60.0 mmol), 4,6-dichloropyrimidine (Pym) (8.5 g, 57.6 mmol), and potassium carbonate (11.1 g, 81.0 mmol) were weighed in a four-necked separable flask with a stirring device. N-Methyl-2-pyrrolidone (64 g) was added, and the whole was subjected to a reaction under a nitrogen atmosphere at 130° C. for 8 hours. After the completion of the reaction, N-methyl-2-pyrrolidone (368 g) was added, and a salt was removed by filtration. After that, the remaining solution was charged into methanol (9.1 kg). A precipitated solid was separated by filtration and washed with a small amount of methanol. The solid was separated by filtration again and recovered, and was then dried with a vacuum dryer under reduced pressure at 120° C. for 12 hours to provide a polymer P-11 having a structural unit represented by the following formula (P-11) (yield; 22.9 g, percent yield; 90%, weight-average molecular weight (Mw); 30,000, glass transition temperature (Tg); 153° C.).

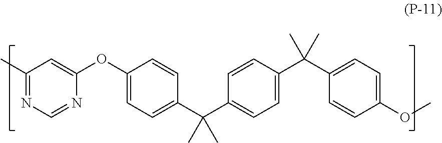

### Synthesis Example 12

4,4′-(1-Phenylethane-1,1-diyl))diphenol (BisP) (17.4 g, 60.0 mmol), 4,6-dichloropyrimidine (Pym) (8.5 g, 57.6 mmol), and potassium carbonate (11.1 g, 81.0 mmol) were weighed in a four-necked separable flask with a stirring device. N-Methyl-2-pyrrolidone (64 g) was added, and the whole was subjected to a reaction under a nitrogen atmosphere at 130° C. for 8 hours. After the completion of the reaction, N-methyl-2-pyrrolidone (368 g) was added, and a salt was removed by filtration. After that, the remaining solution was charged into methanol (9.1 kg). A precipitated solid was separated by filtration and washed with a small amount of methanol. The solid was separated by filtration again and recovered, and was then dried with a vacuum dryer under reduced pressure at 120° C. for 12 hours to provide a polymer P-12 having a structural unit represented by the following formula (P-12) (yield; 20.3 g, percent yield; 92%, weight-average molecular weight (Mw); 28,000, glass transition temperature (Tg); 184° C.).

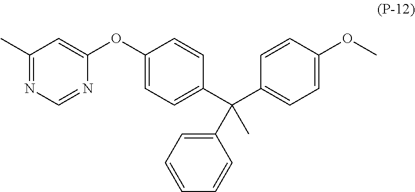

Synthesis of Comparative Sample

### <Synthesis of PPE>

A four-necked flask with a stirring device, a temperature gauge, a Dimroth condenser, and an oxygen (air) bubbling tube was loaded with copper(I) chloride (51.8 mg, 0.52 mmol), toluene (100 g), pyridine (1.58 g, 20 mmol), and 2,6-dimethylphenol (14.5 g, 120 mmol), and the contents were subjected to a reaction under air bubbling at 40° C. for 6 hours. After the completion of the reaction, the resultant was washed with 1% hydrochloric acid, and the organic layer was solidified with methanol. The resultant was dried with a vacuum dryer under reduced pressure at 120° C. for 12 hours to provide PPE as pale yellow powder (yield: 10.2 g, 85 mmol, 70.8%). weight-average molecular weight (Mw); 35,000, glass transition temperature (Tg); 200° C.).

5.3. Production of Prepreg

### Example 1

50 Parts of the polymer P-1, 50 parts of 2,2′-bis(4-cyanatophenyl)propane (manufactured by Tokyo Chemical Industry Co., Ltd.) serving as a curable compound, 5 parts of 1-benzyl-2-methylimidazole (manufactured by Mitsubishi Chemical Corporation, product name: “BMI 12”) serving as a curing aid, and 100 parts of cyclopentanone were mixed to prepare a resin composition. An NE-glass cloth (style: 2116) (having a dielectric constant of 4.8 and a dielectric loss tangent of 0.0015 at 1 GHz) was impregnated therewith, was then passed through a predetermined slit to scrape off an excess varnish, and was heated with an oven at 70° C. for 10 minutes and then further heated at 130° C. for 10 minutes to provide a prepreg. The prepreg was subjected to vacuum press in a state of having copper foil (manufactured by Mitsui Kinzoku, model number: “TQ-M4-VSP”, surface roughness: 110 nm) overlaid on both surfaces thereof to provide a copper-clad laminate. This vacuum press process involved heating and pressurization under the press conditions of 120° C./1.1 MPa/2 minutes, and further heating at 250° C. for 3 hours. Next, the copper foil was removed from the copper-clad laminate by etching to provide a laminate.

<Examples 2 to 20 and Comparative Examples 1 to 4>

Varnishes were prepared by the same method as in Example 1 except that materials were used as shown in Tables 1 to 3 below. In addition, prepregs were produced by the same method as in Example 1. Further, with use of those prepregs, copper-clad laminates and laminates from which copper foil had been removed were obtained by the same method as in Example 1.

5.4. Evaluation Methods

5.4.1. Evaluation of Prepreg

### <Resin Content>

The prepregs produced above were each cut into a predetermined size, and the weight of the resultant and the weight of a glass cloth of the same size were compared to calculate the weight content ratio (%) of the solid content of the resin composition in the prepreg. The results are shown in Tables 1 to 3 below. The weight content ratio of the resin solid content in the prepreg is calculated by the following equation, where the weight of the prepreg is represented by Wp (g/m²) and the weight of the glass cloth is represented by Wg (g/m²).

Weight content ratio (%)=(Wp−Wg)/Wp×100

<External Appearance>

After impregnation with the resin composition and drying, the state of each of the prepregs was visually observed. Evaluation criteria are as described below. Evaluation results are shown in Tables 1 to 3 below.

### (Evaluation Criteria)

A: None of cracking, breakage, a mass, and nonuniformity is found.
B: Slight cracking, breakage, a mass, or nonuniformity is found, but there is no problem in use.
C: Cracking, breakage, a mass, or nonuniformity is found, and there is a problem in use.

<Bending Peeling>

The prepregs produced above were each cut into a size of 100 mmx 150 mm, and evaluation was performed by visually observing whether or not a problem, such as cracking, breakage, chipping, or peeling, occurred when the cut piece was bent by 180°. Evaluation criteria are as described below. Evaluation results are shown in Tables 1 to 3 below.

### (Evaluation Criteria)

A: Judged acceptable because none of the problems, such as cracking, breakage, chipping, and peeling, is found.
B: Judged unacceptable because any one of the problems, such as cracking, breakage, chipping, and peeling, occurred.

5.4.2. Evaluation of Copper-clad Laminate

<Adhesiveness with Copper Foil>

A test piece having a size of 10 mm×100 mm was cut out of each of the copper-clad laminates produced above, and was measured for its peeling strength in conformity with “IPC-TM-650 2.4.9” by being pulled in the direction of 90° under the condition of 500 mm/min with “Instron 5567” manufactured by Instron. Evaluation criteria are as described below. Evaluation results are shown in Tables 1 to 3 below.

### (Evaluation Criteria)

A: Judged acceptable because of having a peel strength of 0.3 N/mm or more, i.e., having a sufficient peeling strength.

B: Judged unacceptable because of having a peel strength of less than 0.3 N/mm, i.e., having an insufficient peeling strength.

5.5. Evaluation Results

The compositions of the resin compositions used in Examples 1 to 20© and Comparative Examples 1 to 4, the physical properties of the respective polymers, and the respective evaluation results are summarized in Tables 1 to 3 below.

TABLE 1

| | | | Example | Example | Example | Example | Example | Example | Example | Example |
|---|---|---|---|---|---|---|---|---|---|---|
| | | | 1 | 2 | 3 | 4 | 5 | 6 | 7 | 8 |
| Specific | Kind | | P-1 | P-1 | P-2 | P-3 | P-3 | P-3 | P-3 | P-3 |
| polymer | Mw | | 28,000 | 28,000 | 7,000 | 90,000 | 90,000 | 90,000 | 90,000 | 90,000 |
| | Tg (° C.) | | 206 | 206 | 180 | 206 | 206 | 206 | 206 | 206 |
| | Parts by mass | | 50 | 50 | 50 | 50 | 25 | 20 | 43 | 40 |
| Other | Kind | | — | — | Tuftec | — | Ricon | Tuftec | — | Noryl |
| polymer | | | | | M1913 | | 100 | M1913 | | SA90 |
| | Mw | | — | — | — | — | — | — | — | 3,500 |
| | Parts by mass | | — | — | 50 | — | 50 | 50 | — | 5 |
| Curable | Kind | | BCPP | BCPP | BCPP | BCPP | BCPP | BCPP | BMI-70 | BCPP |
| compound | Parts by mass | | 50 | 25 | 12.5 | 25 | 25 | 12.5 | 43 | 40 |
| | Kind | | — | DCBPCY | DCBPCY | BMI-70 | — | DCBPCY | — | — |
| | Parts by mass | | — | 25 | 12.5 | 25 | — | 12.5 | — | — |
| Flame | DBDE | Parts | — | — | — | — | 1 | — | — | 1 |
| retardant | | by | | | | | | | | |
| | | mass | | | | | | | | |
| | Rabitle | Parts | — | 15 | — | 15 | — | — | 14 | — |
| | FP-100 | by | | | | | | | | |
| | | mass | | | | | | | | |
| Curing aid | PERCUMYL | Parts | — | — | 2.5 | 5 | — | 2.5 | 2.5 | — |
| | D | by | | | | | | | | |
| | | mass | | | | | | | | |
| | BMI12 | Parts | 5 | 5 | — | — | 1.3 | — | 5 | 5 |
| | | by | | | | | | | | |
| | | mass | | | | | | | | |
| Base | Glass cloth | Kind | NE | NE | NE | NE | NE | NE | NE | NE |
| material | | | | | | | | | | |

| | | | | | | | | | |
|---|---|---|---|---|---|---|---|---|---|
| Prepreg | Resin content | 54 | 54 | 53 | 55 | 55 | 52 | 52 | 52 |
| | (weight content | | | | | | | | |
| | ratio: %) | | | | | | | | |
| | External appearance | A | A | A | A | A | A | A | A |
| | Bending peeling | A | A | A | A | A | A | A | A |
| Copper-clad | Dielectric | 3.4/0.006 | 3.4/0.005 | 3.2/0.003 | 3.4/0.004 | 3.1/0.002 | 3.2/0.004 | 3.4/0.005 | 3.4/0.005 |
| laminate | constant/loss tangent | | | | | | | | |
| | at 1 GHz | | | | | | | | |
| | Adhesiveness with | A | A | A | A | A | A | A | A |
| | copper foil | | | | | | | | |

TABLE 2

| | | | Example | Example | Example | Example | Example | Example | Example | Example |
|---|---|---|---|---|---|---|---|---|---|---|
| | | | 9 | 10 | 11 | 12 | 13 | 14 | 15 | 16 |
| Specific | Kind | | P-3 | P-3 | P-3 | P-4 | P-5 | P-6 | P-7 | P-8 |
| polymer | Mw | | 90,000 | 90,000 | 90,000 | 30,000 | 187,000 | 165,000 | 157,000 | 25,000 |
| | Tg (° C.) | | 206 | 206 | 206 | 232 | 223 | 196 | 190 | 156 |
| | Parts by mass | | 25 | 25 | 43 | 50 | 50 | 50 | 50 | 50 |
| Other | Kind | | Noryl | Noryl | Noryl | — | — | — | — | — |
| polymer | | | SA90 | SA90 | SA9000 | | | | | |
| | Mw | | | | | | | | | |
| | Parts by mass | | 25 | 25 | 21.5 | — | — | — | — | — |
| Curable | Kind | | BCPP | — | — | BCPP | BCPP | BCPP | BCPP | BCPP |
| compound | Parts by mass | | 50 | — | — | 50 | 50 | 50 | 50 | 50 |
| | Kind | | — | TAIC | L-DAIC | — | — | — | — | 1 |
| | Parts by mass | | — | 25 | 21.5 | — | — | — | — | — |
| Flame | DBDE | Parts | 15 | — | — | — | — | — | — | — |
| retardant | | by | | | | | | | | |
| | | mass | | | | | | | | |
| | Rabitle | Parts | — | 15 | 14 | — | — | — | — | — |
| | FP-100 | by | | | | | | | | |
| | | mass | | | | | | | | |
| Curing aid | PERCUMYL | Parts | — | 5 | 2.5 | — | — | — | — | — |
| | D | mass | | | | | | | | |
| | BMI12 | Parts | 5 | — | — | 5 | 5 | 5 | 5 | 5 |
| | | by | | | | | | | | |
| | | mass | | | | | | | | |
| Base | Glass cloth | Kind | NE | NE | NE | NE | NE | NE | NE | NE |
| material | | | | | | | | | | |

| | | | | | | | | | |
|---|---|---|---|---|---|---|---|---|---|
| Prepreg | Resin content | 54 | 54 | 55 | 54 | 54 | 53 | 52 | 54 |
| | (weight content | | | | | | | | |
| | ratio: %) | | | | | | | | |
| | External appearance | A | A | A | A | A | A | A | B |
| | Bending peeling | A | A | A | A | A | A | A | A |
| Copper-clad | Dielectric | 3.5/0.005 | 3.4/0.006 | 3.2/0.002 | 3.4/0.006 | 3.3/0.004 | 3.2/0.004 | 3.2/0.003 | 3.47/0.006 |
| laminate | constant/loss tangent | | | | | | | | |
| | at 1 GHz | | | | | | | | |
| | Adhesiveness with | A | A | A | A | A | A | A | A |
| | copper foil | | | | | | | | |

TABLE 3

| | | | | | | | Compar- | Compar- | Compar- | Compar- |
|---|---|---|---|---|---|---|---|---|---|---|
| | | | | | | | ative | ative | ative | ative |
| | | | Example | Example | Example | Example | Example | Example | Example | Example |
| | | | 17 | 18 | 19 | 20 | 1 | 2 | 3 | 4 |
| Specific | Kind | | P.9 | P-10 | P-11 | P-12 | — | — | — | — |
| polymer | Mw | | 65,000 | 25,000 | 30,000 | 28,000 | — | — | — | — |
| | Tg (° C.) | | 130 | 112 | 153 | 184 | — | — | — | — |
| | Parts by mass | | 50 | 50 | 50 | 50 | — | — | — | — |
| Other | Kind | | — | — | — | — | PPE | PPE | Noryl SA90 | Noryl SA90 |
| polymer | Mw | | — | — | — | — | 35,000 | 35,000 | | |
| | Parts by mass | | — | — | — | — | 50 | 50 | 50 | 43 |
| Curable | Kind | | BCPP | BCPP | BCPP | BCPP | BCPP | — | BCPP | BMI-70 |
| compound | Parts by mass | | 50 | 50 | 50 | 50 | 50 | — | 50 | 43 |
| | Kind | | — | — | — | — | — | TAIC | — | — |
| | Parts by mass | | — | — | — | — | — | 36 | — | — |
| Flame | DBDE | Parts | — | — | — | — | — | — | — | — |
| retardant | | by | | | | | | | | |
| | | mass | | | | | | | | |
| | Rabitle | Parts | — | — | — | — | — | 14 | — | 14 |
| | FP-100 | by | | | | | | | | |
| | | mass | | | | | | | | |
| Curing aid | PERCUMYL | Parts | — | — | — | — | — | — | — | 2.5 |
| | D | by | | | | | | | | |
| | | mass | | | | | | | | |
| | BMI12 | Parts | 5 | 5 | 5 | 5 | 5 | 5 | 5 | — |
| | | by | | | | | | | | |
| | | mass | | | | | | | | |
| Base | Glass cloth | Kind | NE | NE | NE | NE | NE | NE | NE | NE |
| material | | | | | | | | | | |

| | | | | | | | | | |
|---|---|---|---|---|---|---|---|---|---|
| Prepreg | Resin content | 53 | 54 | 54 | 54 | 50 | 50 | 49 | 48 |
| | (weight content | | | | | | | | |
| | ratio: %) | | | | | | | | |
| | External appearance | B | A | A | A | C | C | 0 | C |
| | Bending peeling | A | A | A | A | B | B | B | B |
| Copper-clad | Dielectric | 3.4/0.005 | 3.4/0.004 | 3.4/0.005 | 3.4/0.006 | * | * | 3.4/0.006 | 3.4/0.006 |
| laminate | constant/loss tangent | | | | | | | | |
| | at 1 GHz | | | | | | | | |
| | Adhesiveness with | A | A | A | A | B | B | B | B |
| | copper foil | | | | | | | | |

* : indicates that no evaluable sample could be obtained.

Abbreviations or product names in Tables 1 to 3 above refer to the following compounds.

### <Other Polymer>

Tuftec™ M1913: manufactured by Asahi Kasei Corporation, hydrogenated styrene-based thermoplastic elastomer
Ricon™ 100: manufactured by Cray Valley, butadiene-styrene random copolymer
PPE: in-house synthetic polyphenylene ether (the above-mentioned comparative sample synthetic product), Mw=35,000
   Noryl SA90: manufactured by Sabic, reactive low-molecular-weight polyphenylene ether, Mw=3,9500
   Noryl SA9000: manufactured by Sabic, reactive low-molecular-weight polyphenylene ether

### <Curable Compound>

BCPP: manufactured by Tokyo Chemical Industry Co., Ltd., 2,2′-bis(4-cyanatophenyl)propane
BMI-70: manufactured by K⋅I Chemical Industry Co, Ltd., bis-(3-ethyl-5-methyl-4-maleimidophenyl)methane
DCBPCY: dicyclopentadienyl cyanate ester (compound represented by the above-mentioned formula (c2-7))
TAIC: manufactured by Mitsubishi Chemical Corporation, triallyl isocyanurate
L-DAIC: manufactured by Shikoku Kasei Holdings Corporation, diallyl alkyl isocyanurate

### <Flame Retardant>

DBDE: manufactured by Fujifilm Wako Pure Chemical Corporation, decabromodiphenylethane
Rabitle™ FP-100: manufactured by Fushimi Pharmaceutical Co., Ltd., hexaphenoxycyclotriphosphazene

### <Curing Aid>

Percumyl™ D: manufactured by NOF Corporation, dicumyl peroxide, polymerization initiator
BMI12: manufactured by Mitsubishi Chemical Corporation, 1-benzyl-2-methylimidazole

### <Glass Cloth>

NE: manufactured by Nitto Boseki Co., Ltd., NE-glass cloth (style: 2116)

It was recognized from the results of Tables 1 to 3 above that the prepregs of Examples 1 to 20 containing the glass cloth and the specific polymer each enabled the production of a copper-clad laminate which was able to have its dielectric constant and dielectric loss tangent kept low, had high reliability with a satisfactory external appearance, and was also excellent in adhesiveness with the base material or the like. Meanwhile, it was recognized that the prepregs of Comparative Examples 1 to 4 not containing the specific polymer had low reliability due to an external appearance failure, and were also inferior in adhesiveness with the base material or the like.

The present invention is not limited to the embodiments described above, and various modifications may be made thereto. The present invention encompasses substantially the same configurations as the configurations described in the embodiments (e.g., configurations having the same functions, methods, and results, or configurations having the same objects and effects). The present invention also encompasses configurations obtained by replacing non-essential parts of the configurations described in the embodiments with other configurations. The present invention also encompasses configurations exhibiting the same actions and effects or configurations capable of achieving the same objects as those of the configurations described in the embodiments. The present invention also encompasses configurations obtained by adding known technologies to the configurations described in the embodiments.

1: A prepreg, comprising:
a base material; and
a polymer having a structural unit represented by at least one kind of the following formulae (1-1), (1-2), and (1-3): 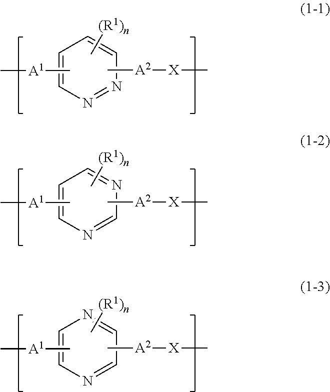
in the formulae (1-1) to (1-3), R¹s each independently represent a halogen atom, a monovalent hydrocarbon group having 1 to 20 carbon atoms, a monovalent halogenated hydrocarbon group having 1 to 20 carbon atoms, a nitro group, a cyano group, a primary to tertiary amino group, or a salt of a primary to tertiary amino group, “n”s each independently represent an integer of from 0 to 2, and when “n” represents 2, a plurality of R¹s may be identical to or different from each other, or may be bonded to each other in an arbitrary combination to form part of a ring structure, A¹ and A² each independently represent —O—, —S—, or —N(R²)—, R² represents a hydrogen atom, a monovalent hydrocarbon group having 1 to 20 carbon atoms, or a monovalent halogenated hydrocarbon group having 1 to 20 carbon atoms, and X represents a divalent organic group.

2: The prepreg according to claim 1, wherein the divalent organic group represented by the X in the formulae (1-1) to (1-3) contains a group represented by the following formula (2-1): 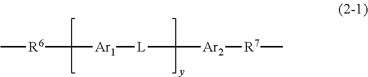
in the formula (2-1), Ar₁ and Ar₂ each independently represent a substituted or unsubstituted aromatic hydrocarbon group, L represents a single bond, —O—, —S—, —N(R⁸), C═O, —SO₂—, P═O, or a divalent organic group, R⁸ represents a hydrogen atom, a monovalent hydrocarbon group having 1 to 20 carbon atoms, or a monovalent halogenated hydrocarbon group having 1 to 20 carbon atoms, “y” represents an integer of from 0 to 5, and when “y” represents 2 or more, a plurality of Ls may be identical to or different from each other, and R⁶ and R⁷ each independently represent a single bond, a methylene group, or an alkylene group having 2 to 4 carbon atoms.

3: The prepreg according to claim 1, further comprising a curable compound.

4: The prepreg according to claim 1, further comprising:
a curing agent;
a curing aid;
a flame retardant; and
an inorganic filler.

5: The prepreg according to claim 1,
wherein the base material is a glass cloth, and
wherein the glass cloth has a dielectric constant of 6.8 or less.

6: A metal-clad laminate, which is obtained by laminating the prepreg of claim 1 and metal foil, followed by curing.

7: A printed wiring board, comprising the metal-clad laminate of claim 6 from which part of the metal foil has been removed.
